(19) United States
(12) Patent Application Publication
(10) Pub. No.: US 2024/0422977 A1
(43) Pub. Date: Dec. 19, 2024

(54) MICROELECTRONIC DEVICES INCLUDING VERTICAL PLANAR MEMORY CELL STRUCTURES, AND RELATED MEMORY DEVICES AND ELECTRONIC SYSTEMS

(71) Applicant: Micron Technology, Inc., Boise, ID (US)

(72) Inventor: Yoshiaki Fukuzumi, Tokyo (JP)

(21) Appl. No.: 18/667,202

(22) Filed: May 17, 2024

Related U.S. Application Data
(60) Provisional application No. 63/508,333, filed on Jun. 15, 2023.

(51) Int. Cl. H10B 43/27; H10B 43/10

(52) U.S. Cl. CPC H10B 43/27; H10B 43/10

(57) ABSTRACT

A method of forming a microelectronic device includes forming a preliminary stack structure, forming a cell slit extending through the preliminary stack structure, forming oxide separator structures, forming a sacrificial backfill, removing the oxide separator structures to form separator recesses, forming preliminary separator structures in the separator recesses, forming vertical memory string structures within the cell slit, and replacing the sacrificial backfill with conductive material. The preliminary stack structure includes tiers, each tier including a sacrificial material and an insulative material. The oxide separator structures are horizontally adjacent to the cell slit and may vertically extend through the preliminary stack structure. The memory cell material are formed within the cell slit over the preliminary separator structures. The vertical memory string structures vertically extend through the preliminary stack structure and are horizontally separated from one another by separator structures formed from the preliminary separator structures.

### CROSS-REFERENCE TO RELATED APPLICATION

This application claims the benefit under 35 U.S.C. § 119 (c) of U.S. Provisional Patent Application Ser. No. 63/508,333, filed Jun. 15, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices including vertical planar memory cells, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of a tier of the stack structure(s) of the memory device and control logic devices (e.g., string drivers) so that the memory cells of the vertical memory array can be uniquely selected for writing, reading, or erasing operations.

Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1 is a simplified, partial top-down view of a microelectronic device structure at a processing stage of a method of forming a microelectronic device, in accordance with embodiments of the disclosure.

FIGS. 2A through 2Q are simplified, partial perspective cross-sectional views of a portion of the microelectronic device structure shown in FIG. 1 at different processing stages of the method of forming the microelectronic device.

FIG. 3 is a simplified, partial top-down view of a microelectronic device structure, in accordance with additional embodiments of the disclosure.

FIG. 4 is a simplified, partial top-down view of a microelectronic device structure, in accordance with yet additional embodiments of the disclosure.

FIG. 5 is a simplified, partial top-down view of a microelectronic device structure, in accordance with further embodiments of the disclosure.

FIG. 6 is a simplified, partial top-down view of a microelectronic device structure, in accordance with yet further embodiments of the disclosure.

FIG. 7 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. The description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “over,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Moreover, if a material is formed to cover a surface (e.g., a substantially vertical sidewall of a structure), the material may be referred to as being formed “over” the surface even though the material may not be spatially above the covered surface. Likewise, the surface may be referred to as being “under” the formed material. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “hole” and “slit” mean and include a volume extending through at least one structure or at least one material, leaving a void (e.g., gap) in that at least one structure or at least one material, or a volume extending between structures or materials, leaving a gap between the structures or materials. Unless otherwise described, a “hole” and/or “slit” is not necessarily empty of material. That is, a “hole” and/or “slit” is not necessarily void space. A “hole” and/or “slit” formed in or between structures or materials may comprise structure(s) or material(s) other than that in or between which the hole or slit is formed. And, structure(s) or material(s) “exposed” within a “hole” and/or “slit” is (are) not necessarily in contact with an atmosphere or nonsolid environment. Structure(s) or material(s) “exposed” within a “hole” and/or “slit” may be adjacent or in contact with other structure(s) or material(s) that is (are) disposed within the “hole” and/or “slit.”

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, “sacrificial material” means and includes one material that may be selectively removed relative to one or more other materials (e.g., one or more insulative materials). The sacrificial material may be selectively etchable relative to the one or more other materials during common (e.g., collective, mutual) exposure to a first etchant; and the one or more other materials may be selectively etchable to the sacrificial material during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the one or more other materials, the sacrificial material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). The sacrificial material may, for example, be selectively etchable relative to the one or more other materials during common exposure to a wet etchant comprising phosphoric acid (H₃PO₄). In addition, a “sacrificial structure” means and includes a structure formed of and including sacrificial material.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “pitch” refers to a distance between identical points in two adjacent (e.g., neighboring) features of a repeating pattern.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

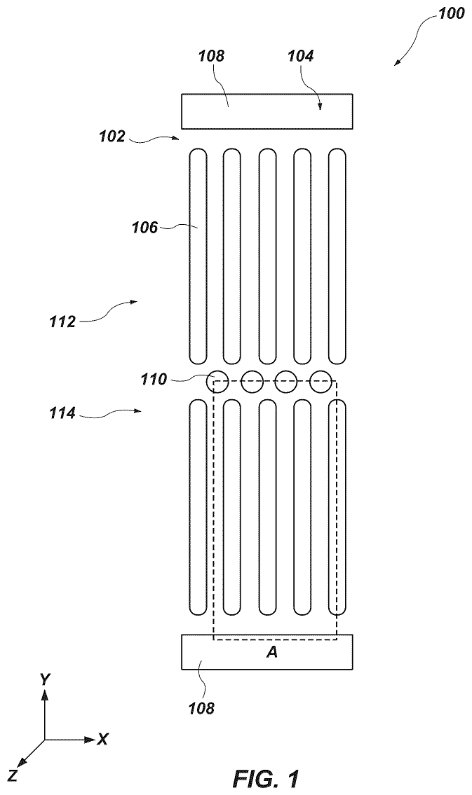

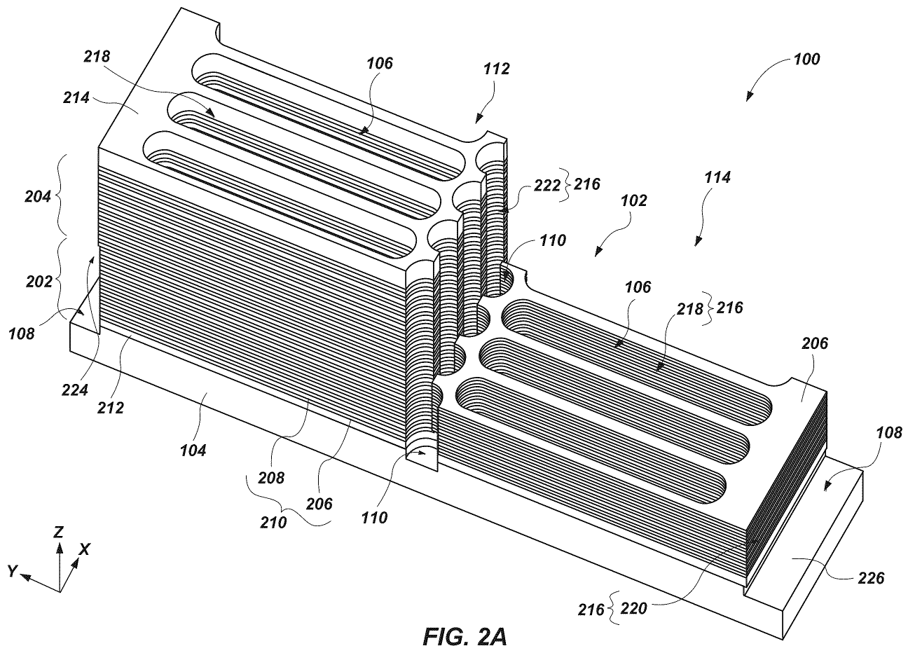

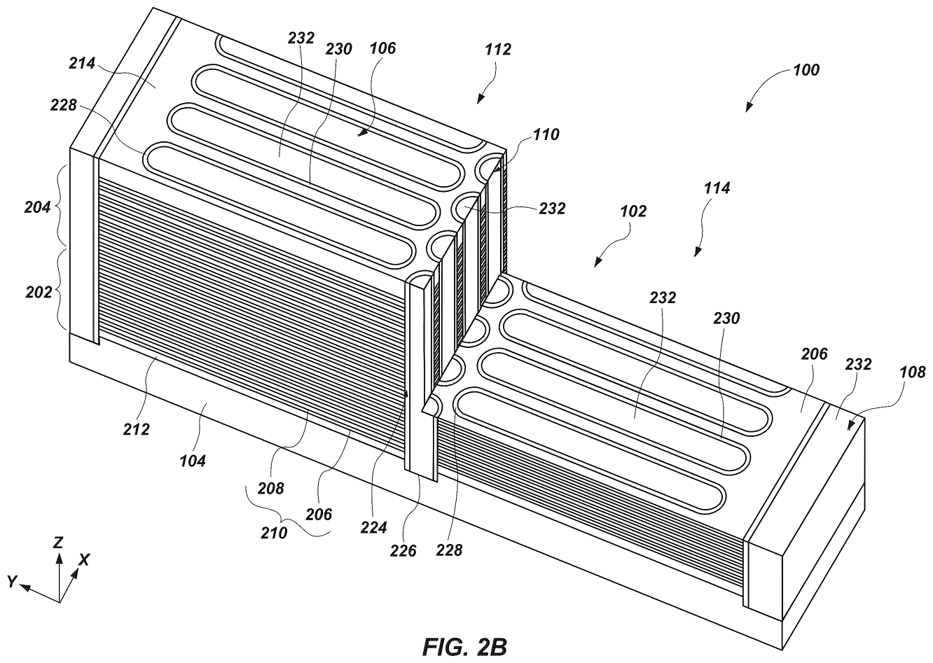

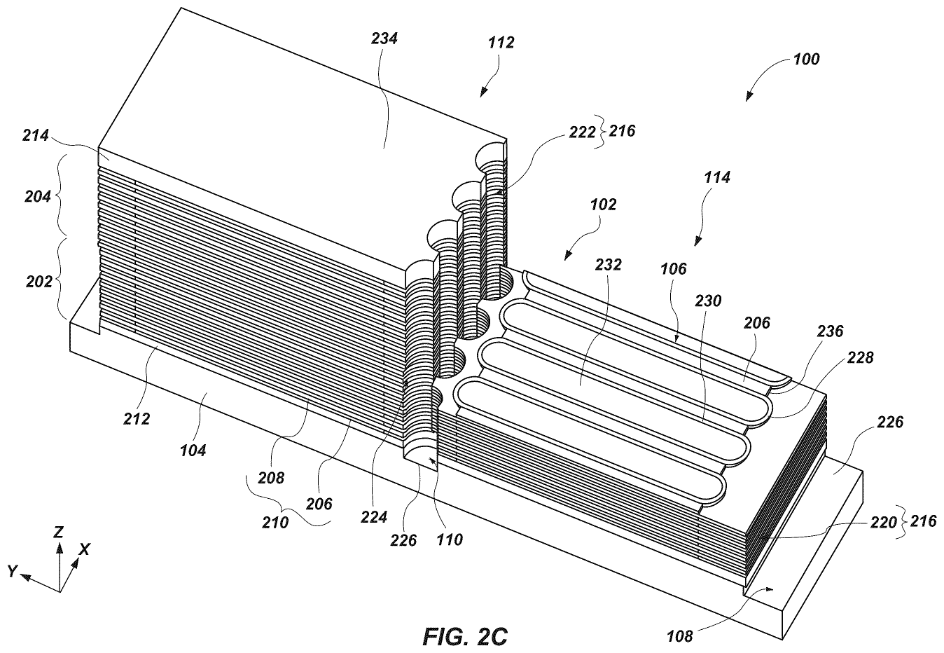

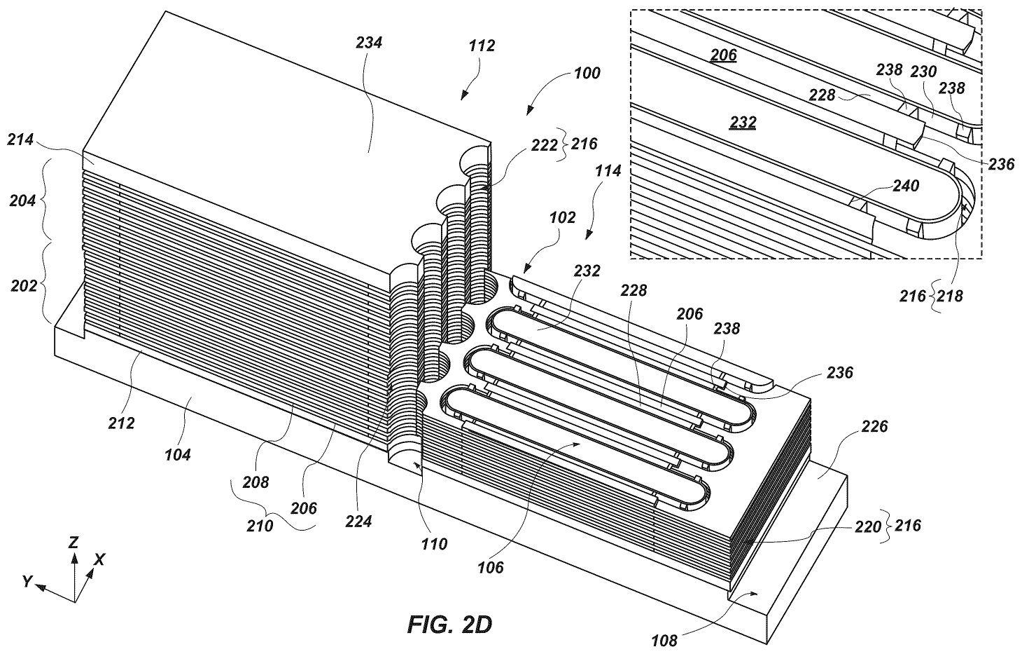

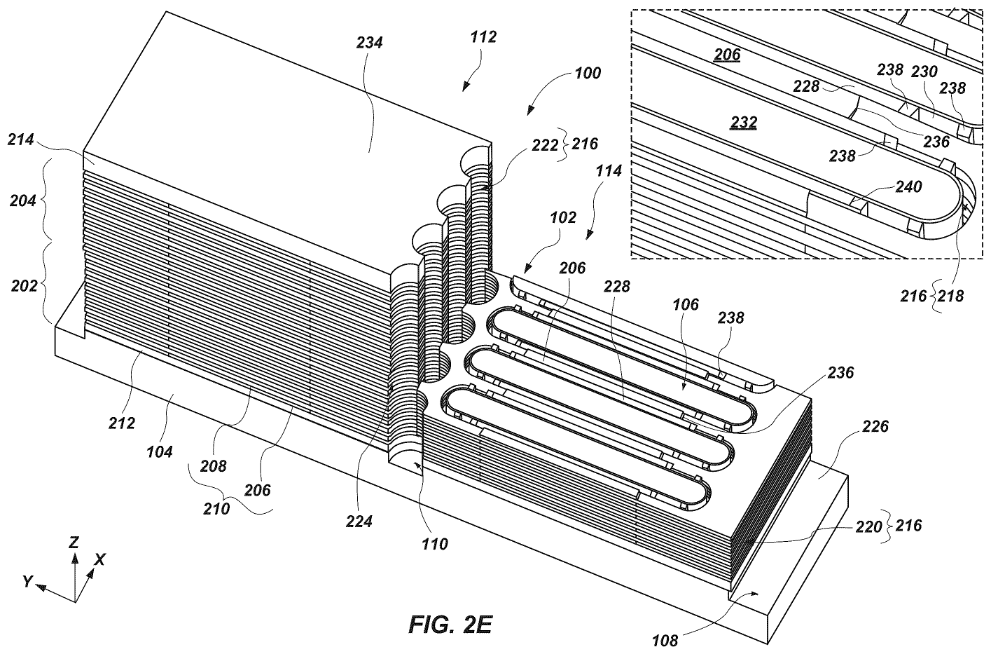

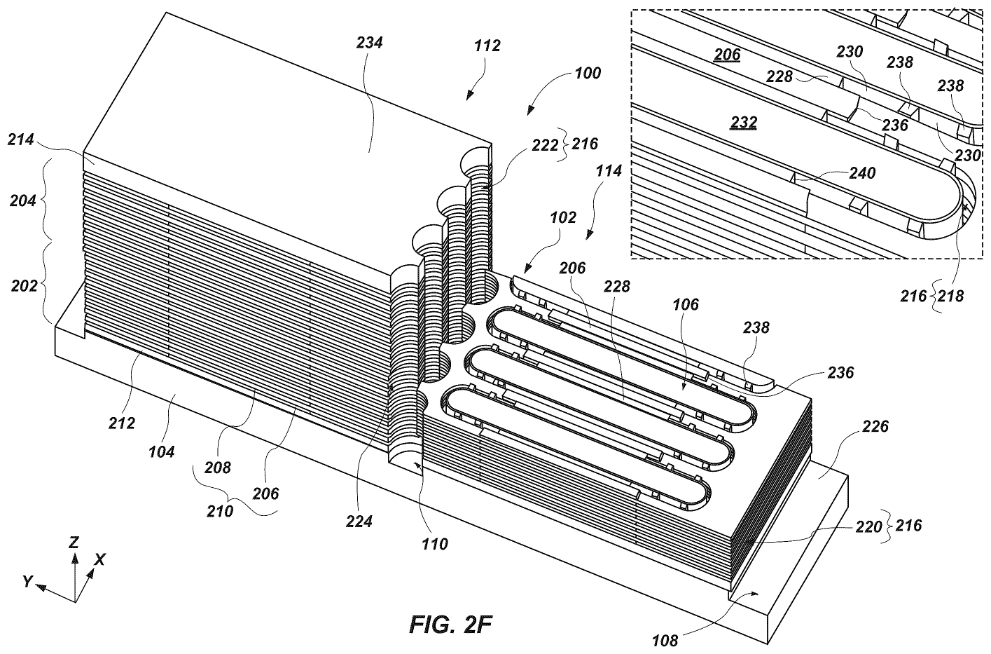

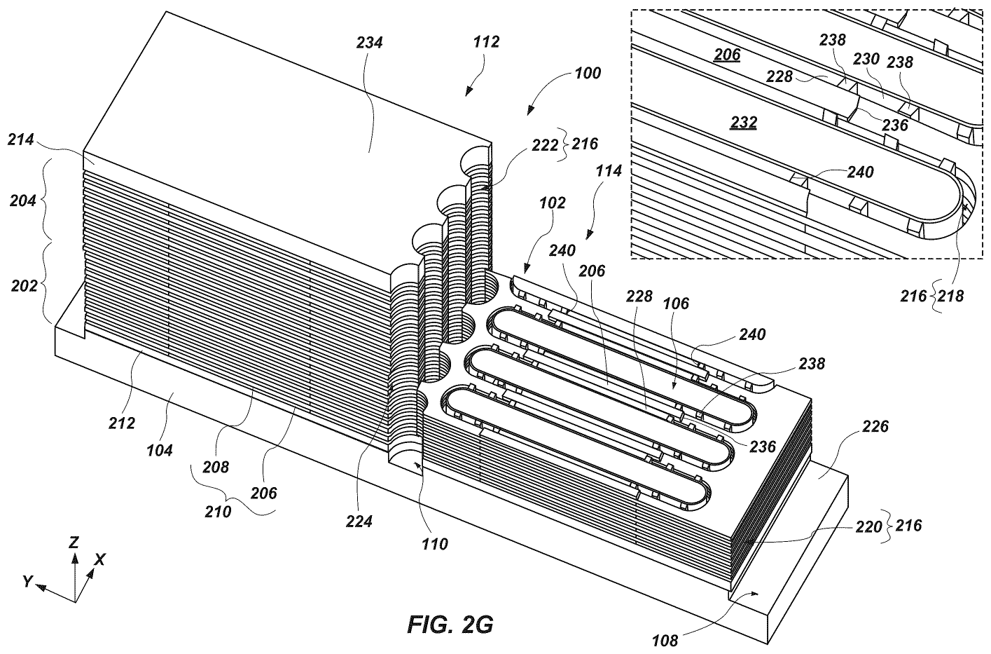

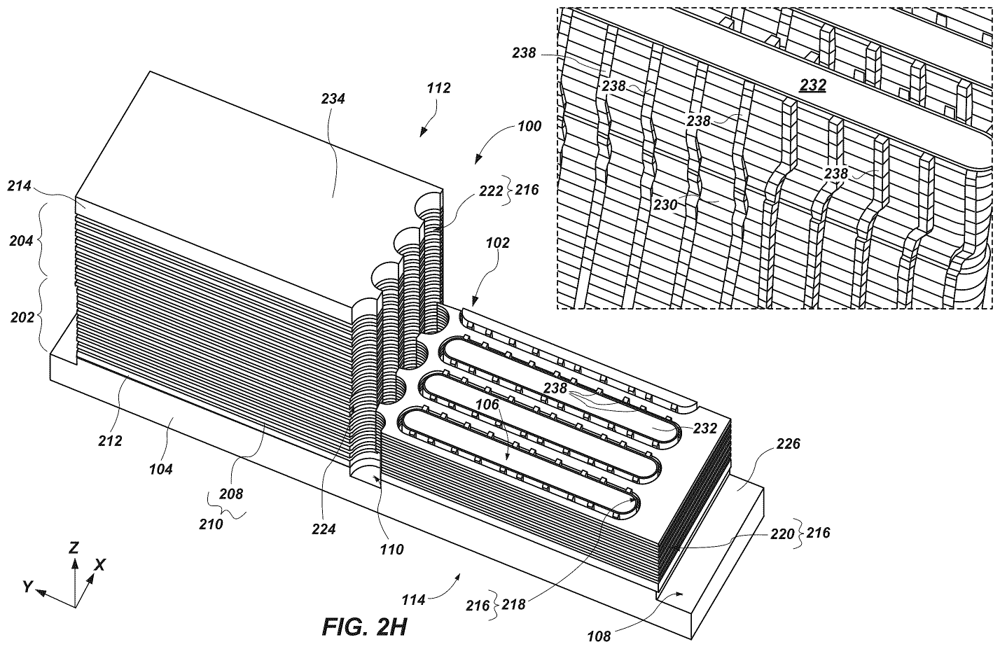

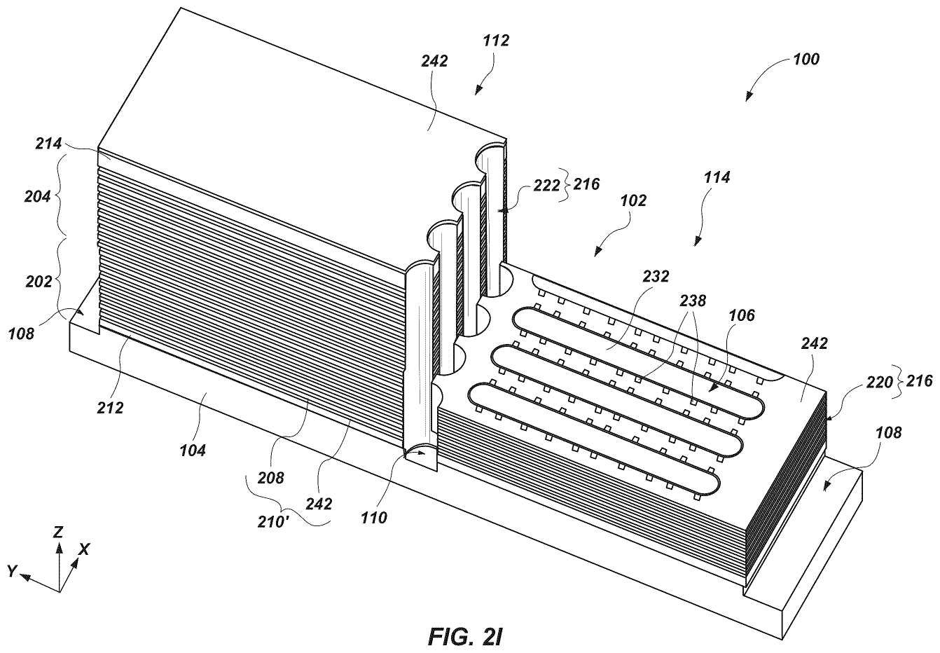

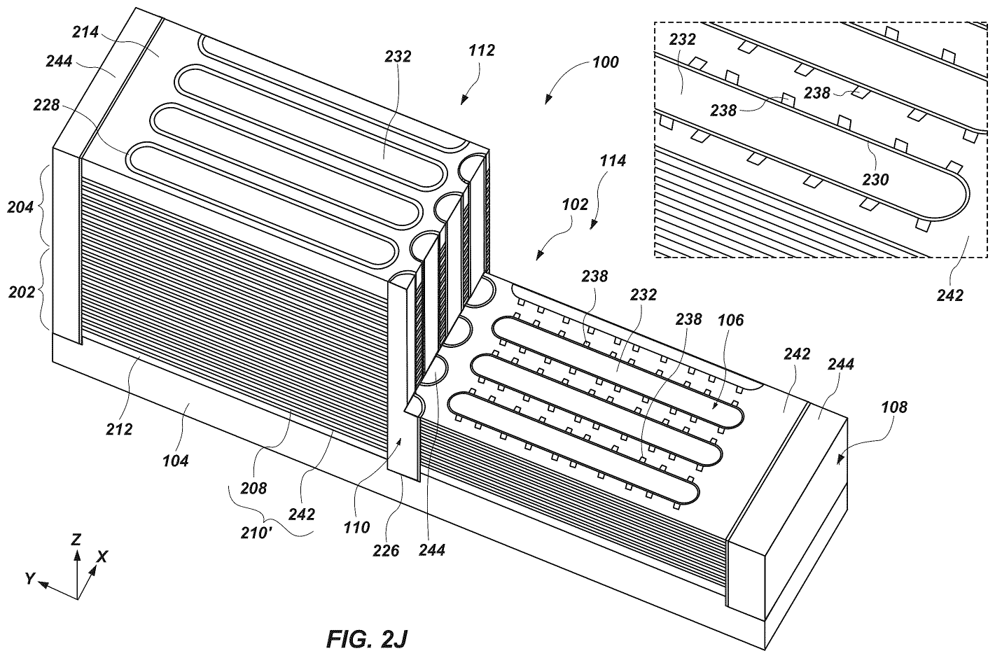

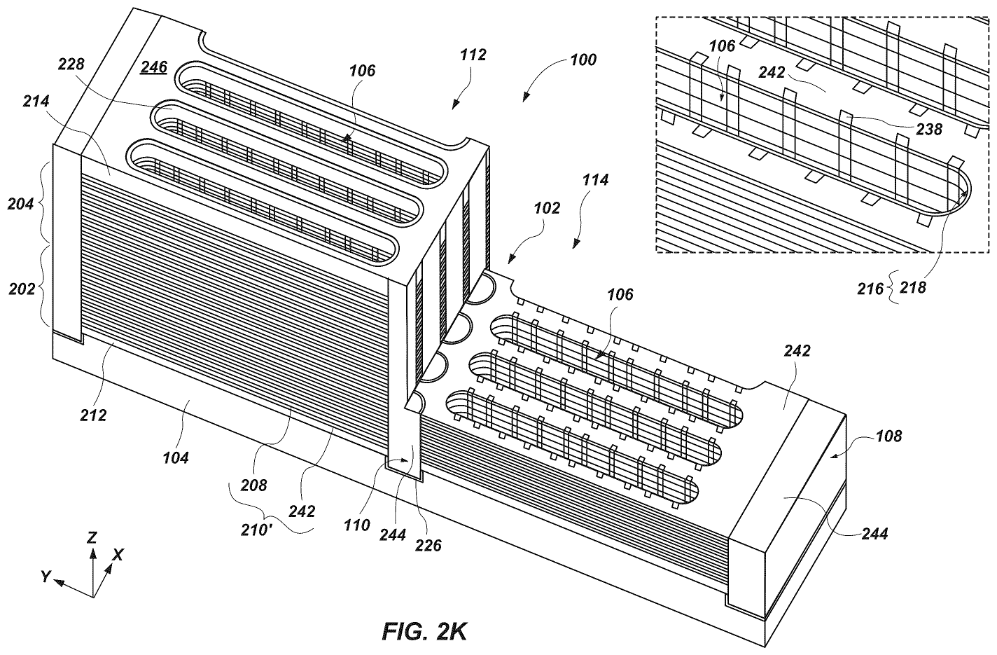

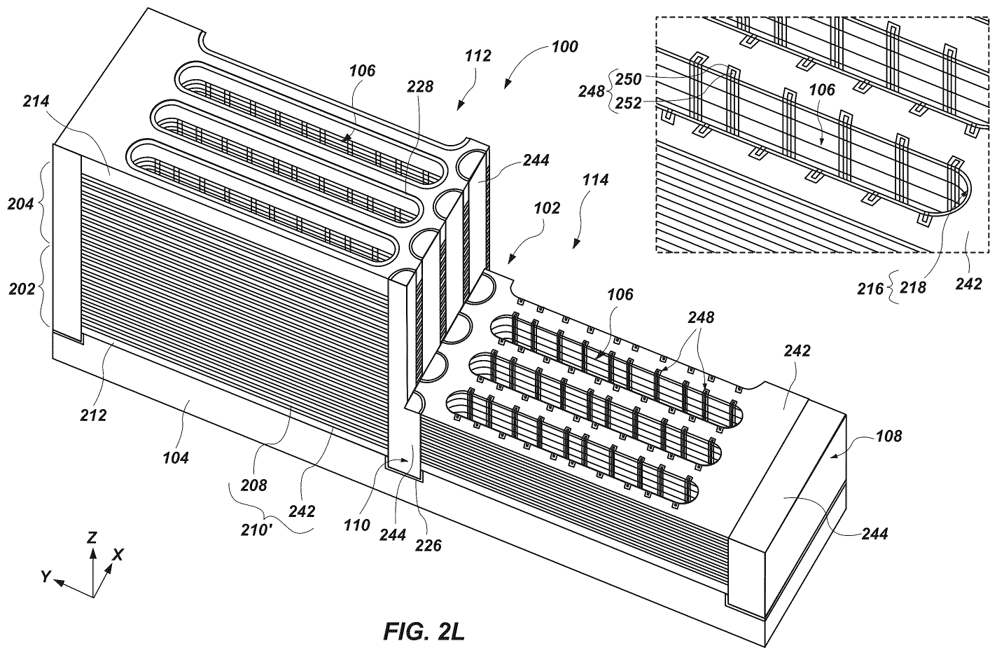

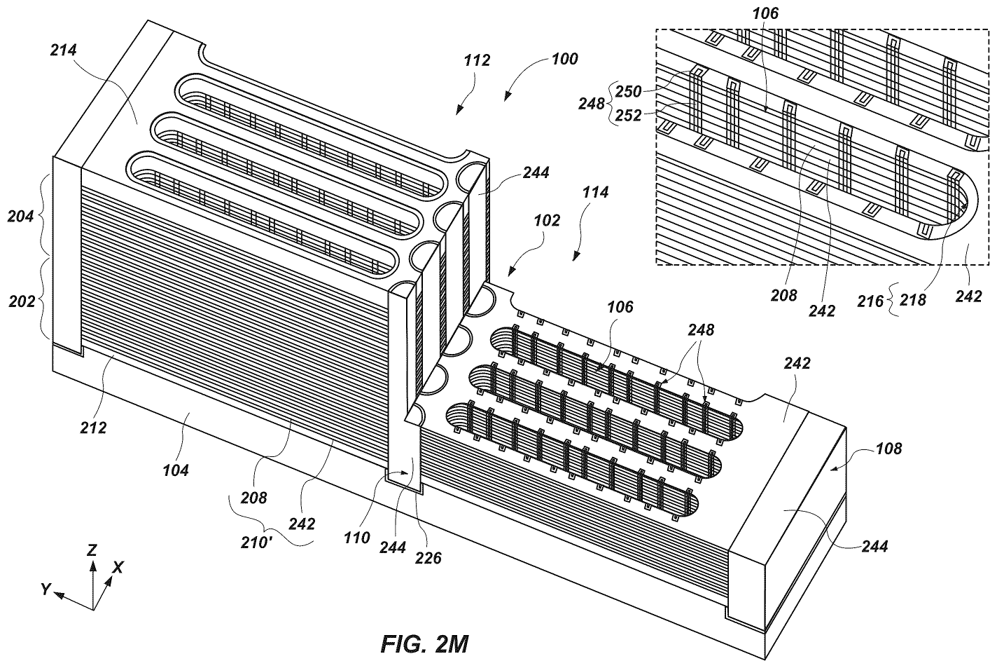

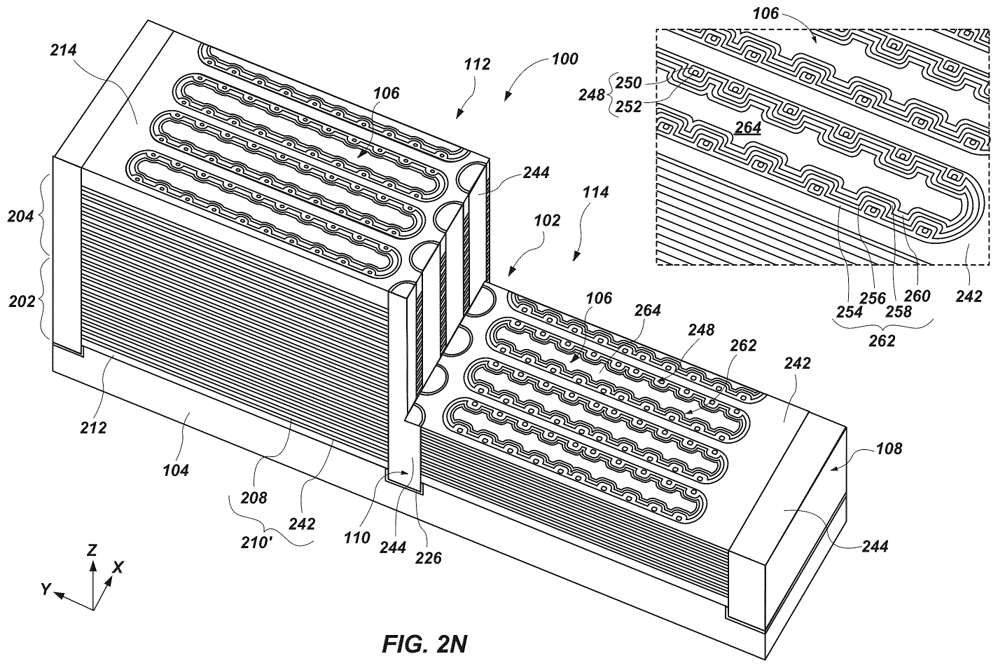

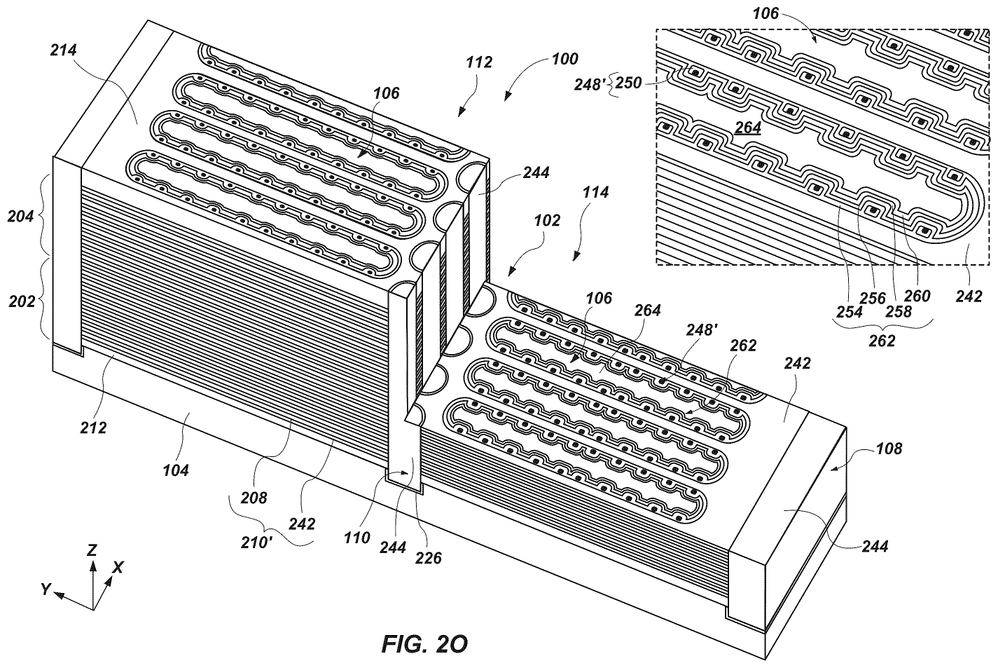

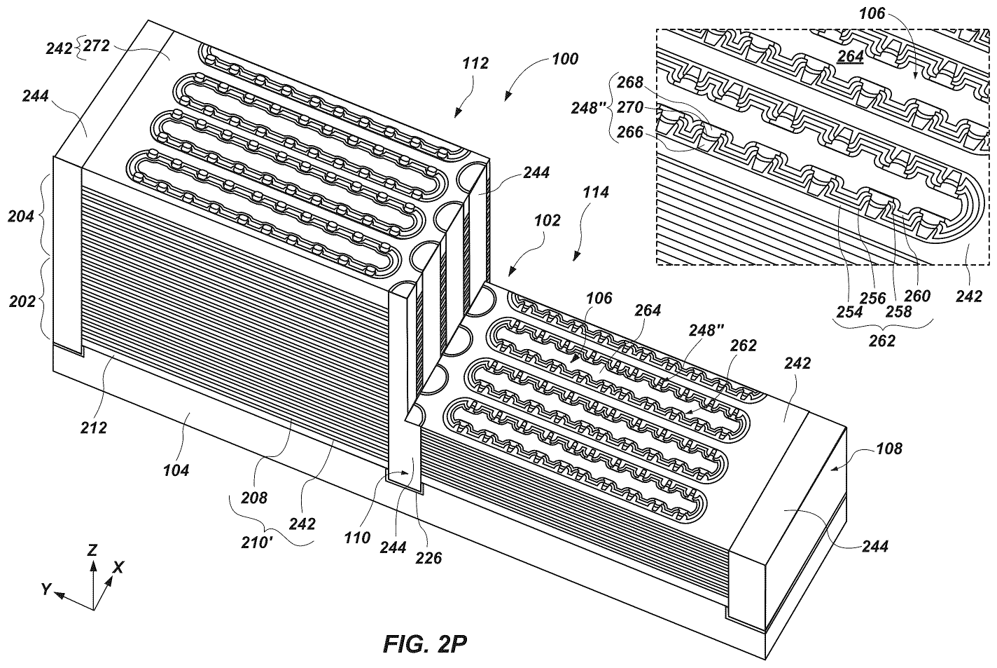

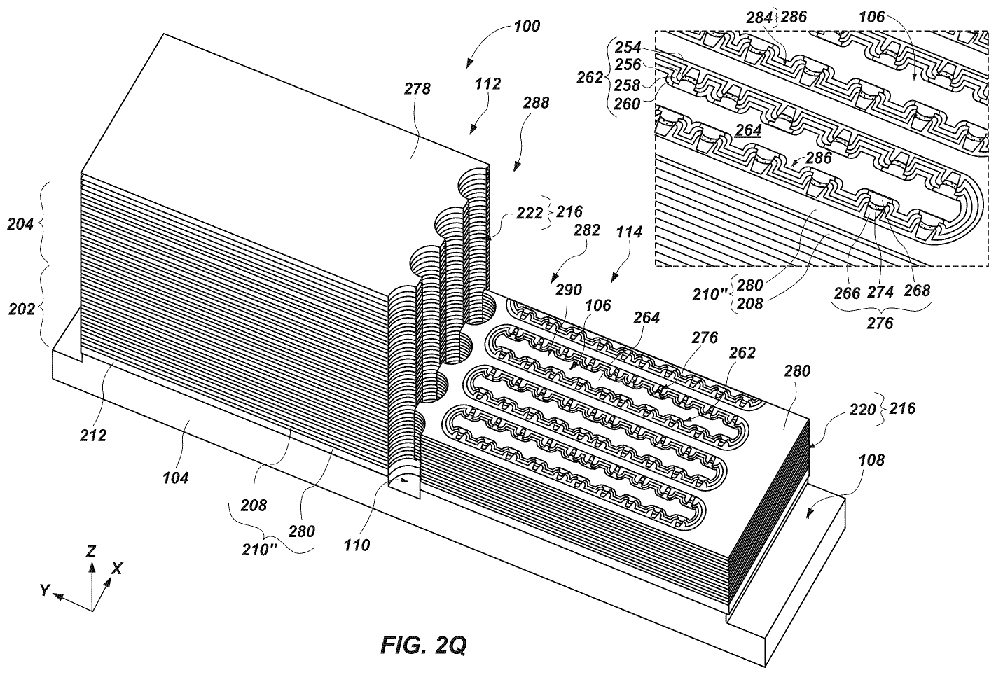

FIG. 1 and FIGS. 2A through 2Q are various views (described in further detail below) illustrating a microelectronic device structure 100 at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and ease of understanding the drawings and associated description, not all features (e.g., regions, structures, materials, devices) of the microelectronic device structure 100 depicted in one or more of FIG. 1 and FIGS. 2A through 2Q are depicted in the one or more other of FIG. 1 and FIGS. 2A through 2Q.

FIG. 1 depicts a simplified, partial top-down view of a microelectronic device structure 100 at a processing stage of a method of forming a microelectronic device, in accordance with embodiments of this disclosure. The microelectronic device structure 100 may be formed to include a preliminary stack structure 102 over a substrate 104. The microelectronic device structure 100 may include one or more cell slits 106, replacement gate slits 108, and linear holes 110 therein. The cell slits 106, the replacement gate slits 108, and the linear holes 110 may define voids vertically extending through the preliminary stack structure 102.

As shown in FIG. 1, the cell slits 106 may include multiple, substantially linear voids in the preliminary stack structure 102. An individual cell slit 106 may include a relatively long edge (e.g., horizontal boundary) horizontally extending in the Y-direction and a relatively short edge horizontally extending in the X-direction substantially orthogonal to the Y-direction. Alternatively, the relatively long edge of an individual cell slit 106 may extend horizontally at an angle that is slightly slanted from the Y-direction. The cell slits 106 may individually exhibit a single, oblong horizontal cross-sectional shape (e.g., an obround horizontal cross-sectional shape). Multiple cell slits 106 horizontally aligned with one another in the Y-direction may be horizontally offset from one another in the X-direction. In addition, cell slits 106 horizontally aligned with one another in the Y-direction may form sets of cell slits 106, such as a first set 112 of the cell slits 106 and a second set 114 of the cell slits 106. The first set 112 and the second set 114 of cell slits 106 may be horizontally offset from one another in the Y-direction.

The replacement gate slits 108 may individually comprise voids (e.g., trenches) vertically extending through the preliminary stack structure 102 and having an elongate horizontal cross-sectional shape (e.g., a substantially rectangular horizontal cross-sectional shape). Individual replacement gate slits 108 may comprise a relatively long edge horizontally extending in the X-direction, and a relatively short edge horizontally extending in the Y-direction. Neighboring replacement gate slits 108 may be individually horizontally spaced from one another in the Y-direction, with multiple sets of cell slits 106 (e.g., the first set 112 of cell slits 106, the second set 114 of cell slits 106) and multiple linear holes 110 disposed therebetween.

As also shown in FIG. 1, the linear holes 110 may individually comprise voids vertically extending through the preliminary stack structure 102 and having a generally circular cross-sectional shape. Multiple linear holes 110 substantially horizontally aligned in the Y-direction may be horizontally offset from one another in the X-direction. The linear holes 110 may be positioned horizontally between (e.g., in the Y-direction) the first set 112 of cell slits 106 and the second set 114 of cell slits 106. Additionally, the linear holes 110 may be individually positioned horizontally between, in the X-direction, two (2) corresponding neighboring cell slits 106 of the first set 112 of the cell slits 106 and two (2) corresponding neighboring cell slits 106 of the second set 114 of the cell slits 106. An individual linear hole 110 may be positioned proximate to four (4) cell slits 106. In some embodiments, an individual linear hole 110 is substantially horizontally centered in the X-direction and the Y-direction between the four (4) cell slits 106 most horizontally proximate thereto. The linear hole 110 may be equidistant from each of the four (4) cell slits 106.

FIGS. 2A through 2Q depict perspective views of the microelectronic device structure 100 at different processing stages of a method of forming a microelectronic device. For clarity and case of understanding the drawings and associated description, a section of the microelectronic device structure 100, indicated by region A in FIG. 1 and having a vertical extent (e.g., in the Z-direction) coincident with an upper portion of the lower deck 202, the upper deck 204, and elements overlying (e.g., in the Z-direction) the upper deck 204 is omitted from view of FIGS. 2A through 2Q.

FIG. 2A is a simplified, partial perspective cross-sectional view of the microelectronic device structure 100, at the processing stage depicted in FIG. 1. As shown in FIG. 2A, the microelectronic device structure 100 may be formed to include the preliminary stack structure 102 including a vertically alternating (e.g., in a Z-direction) sequence of sacrificial material 206 and the insulative material 208 arranged in tiers 210. The tiers 210 of the preliminary stack structure 102 may individually include the sacrificial material 206 vertically neighboring (e.g., directly vertically adjacent in the Z-direction) the insulative material 208.

The insulative material 208 of the individual tiers 210 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbO—ₓ—, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 208 of each of the tiers 210 of the preliminary stack structure 102 is formed of and includes a dielectric oxide material, such as SiOₓ (e.g., SiO₂). The insulative material 208 of each of the tiers 210 may be substantially homogeneous, or the insulative material 208 of one or more (e.g., each) of the tiers 210 may be heterogeneous.

The sacrificial material 206 of each of the tiers 210 of the preliminary stack structure 102 may be formed of and include at least one material (e.g., at least one insulative material) that may be selectively removed relative to the insulative material 208. The sacrificial material 206 may be selectively etchable relative to the insulative material 208 during common (e.g., collective, mutual) exposure to a first etchant; and the insulative material 208 may be selectively etchable to the sacrificial material 206 during common exposure to a second, different etchant. By way of non-limiting example, depending on the material composition of the insulative material 208, the sacrificial material 206 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). In some embodiments, the sacrificial material 206 of each of the tiers 210 of the preliminary stack structure 102 is formed of and includes a dielectric nitride material, such as SiN_{y} (e.g., Si₃N₄). The sacrificial material 206 may, for example, be selectively etchable relative to the insulative material 208 during common exposure to a wet etchant comprising phosphoric acid (H₃PO₄).

The preliminary stack structure 102 may be formed to include any desired number of the tiers 210. By way of non-limiting example, the preliminary stack structure 102 may be formed to include greater than or equal to sixteen (16) of the tiers 210, such as greater than or equal to thirty-two (32) of the tiers 210, greater than or equal to sixty-four (64) of the tiers 210, greater than or equal to one hundred and twenty-eight (128) of the tiers 210, or greater than or equal to two hundred and fifty-six (256) of the tiers 210.

As depicted in FIG. 2A, the microelectronic device structure 100 includes a bottom dielectric material 212 and a top dielectric material 214 at the bottom and top, respectively, of the preliminary stack structure 102. In particular, the bottom dielectric material 212 and the top dielectric material 214 may be respectively situated below and above (e.g., in the Z-direction) the tiers 210. The bottom dielectric material 212 and the top dielectric material 214 may individually be formed of and include insulative material. The bottom dielectric material 212 and the top dielectric material 214 may have substantially the same material composition as one another, or may have different material compositions than one another. The bottom dielectric material 212 and the top dielectric material 214 may individually be vertically thicker (e.g., in the Z-direction) than insulative material 208 of individual tiers 210 of the preliminary stack structure 102. In some embodiments, the top dielectric material 214 is vertically thicker (e.g., in the Z-direction) than the bottom dielectric material 212. The microelectronic device structure 100 may further include a substrate 104, over which the preliminary stack structure 102 may be formed. The substrate 104 may comprise source stack structures such as a polycrystalline silicon film or a stack of multiple polycrystalline silicon films with one or more interfacial films. In some embodiments, the substrate 104 comprises semiconductor structure (e.g., a semiconductor wafer, such as a silicon wafer).

The cell slits 106, replacement gate slits 108, and linear holes 110 may individually be defined as negative space within vertical boundaries of and at least partially defined by the preliminary stack structure 102. The cell slits 106, replacement gate slits 108, and linear holes 110 may individually be further defined as negative space within vertical boundaries of and at least partially defined by the substrate 104. The preliminary stack structure 102 may include sidewalls 216 (e.g., cell slit sidewalls 218, replacement gate slit sidewalls 220, linear hole sidewalls 222) that define horizontal boundaries (e.g., in the X-direction, the Y-direction, and in horizontal directions that are a combination of the X- and Y-directions) of the cell slits 106, replacement gate slits 108, and linear holes 110. Each cell slit 106 may be horizontally bounded by two opposing sidewalls 218 of the preliminary stack structure 102 and of the substrate 104 that face each other in the X-direction. In other words, a pair of opposing sidewalls 218 may form two (2) relatively long horizontal boundaries (e.g., along the Y-direction) of an individual cell slit 106. Each replacement gate slit 108 may be horizontally bounded in one direction (e.g., the Y-direction) by a replacement gate slit sidewall 220 defined by horizontal boundaries of the preliminary stack structure 102 and of the substrate 104. Each linear hole 110 may be horizontally encompassed by a linear hole sidewall 222 defined by annular horizontal boundaries of the preliminary stack structure 102 and of the substrate 104.

The sidewalls 216 of the preliminary stack structure 102 may taper as a result of removal processes (e.g., deep dry etch operations) effectuated on the preliminary stack structure 102 and the substrate 104 to form the cell slits 106, the replacement gate slits 108, and the linear holes 110 therein. Alternatively, the sidewalls 216 may be formed to be substantially vertical. As used in the following description, the sidewalls 216 may include substantially vertical surfaces of the preliminary stack structure 102, of the substrate 104, and/or of other materials formed over the preliminary stack structure 102 and/or over the substrate 104. Further, the sidewalls 216 may include substantially vertical surfaces of a later-formed stack structure 282 and/or of other materials formed over the later-formed stack structure 282.

The preliminary stack structure 102 may be formed to include one or more decks, each deck comprising multiple tiers 210. As depicted in FIG. 2A, the preliminary stack structure 102 may include a lower deck 202 and an upper deck 204 vertically overlying (e.g., in the Z-direction) the lower deck 202. The decks (e.g., lower deck 202, upper deck 204) of the preliminary stack structure 102 may individually include any desired number of tiers 210. By way of non-limiting example, the decks (e.g., lower deck 202, upper deck 204) of the preliminary stack structure 102 may individually include ten (10) tiers 210. Alternatively, the decks of the preliminary stack structure 102 may individually include fewer than ten (10) tiers 210. As further non-limiting examples, the decks of the preliminary stack structure 102 may individually include greater than or equal to ten (10) of the tiers 210, such as greater than or equal to sixteen (16) of the tiers 210, greater than or equal to thirty-two (32) of the tiers 210, greater than or equal to sixty-four (64) of the tiers 210, greater than or equal to one hundred and twenty-eight (128) of the tiers 210, greater than or equal to two hundred and fifty-six (256) of the tiers 210, or greater than or equal to five hundred and twelve (512) of the tiers 210.

As will be described in further detail below, the lower deck 202 and the upper deck 204 may be individually formed during different processing stages. As a result, the upper deck 204 may be partially horizontally (e.g., in the X- and/or Y-directions) offset (e.g., partially horizontally misaligned) with respect to the lower deck 202, thereby resulting in an upper deck overhang 224. A downward-facing lower (e.g., in the Z-direction) edge of the upper deck 204 of the preliminary stack structure 102 may be exposed by the partial horizontal misalignment between the upper deck 204 and the lower deck 202. Alternatively, a horizontal misalignment between the upper deck 204 and the lower deck 202 of the preliminary stack structure 102 may form a shoulder between the lower deck 202 and the upper deck 204. In such embodiments, an upward-facing upper (e.g., in the Z-direction) edge of the lower deck 202 of the preliminary stack structure 102 is exposed by the partial horizontal misalignment between the upper deck 204 and the lower deck 202. In some cases, a horizontal misalignment (e.g., in the X- and/or Y-directions) between the upper deck 204 and the lower deck 202 of the preliminary stack structure 102 may result in tapered sidewalls 216 of the preliminary stack structure 102. Such a tapered sidewall 216 may be positively sloped or may be negatively sloped. In additional embodiments, the preliminary stack structure 102 exhibits substantially no horizontal offset, horizontal misalignment, and/or taper between the lower deck 202 and the upper deck 204.

As described above with respect to FIG. 1, the cell slits 106, the replacement gate slits 108, and the linear holes 110 may individually comprise a void space (e.g., slot, trench, opening, slit) vertically extending (e.g., in the Z-direction) through the preliminary stack structure 102. Within vertical bounds of the preliminary stack structure 102, the cell slits 106, replacement gate slits 108, and linear holes 110 may individually extend vertically (e.g., in the Z-direction) through the top dielectric material 214, the tiers 210 of the upper deck 204 and of the lower deck 202, and the bottom dielectric material 212. Additionally, the cell slits 106, replacement gate slits 108, and/or linear holes 110 may individually extend vertically (e.g., in the Z-direction) partially through the substrate 104. Lower (e.g., in the Z-direction) boundaries of the cell slits 106, replacement gate slits 108, and linear holes 110 may individually be at least partially defined by a surface of the substrate 104.

Forming the microelectronic device structure 100 depicted in FIG. 2A may include forming the preliminary stack structure 102 over the substrate 104. The lower deck 202 of the preliminary stack structure 102 may be formed by forming the bottom dielectric material 212 over the substrate 104, followed by sequentially forming a vertically alternating sequence of the sacrificial material 206 and the insulative material 208.

Following formation of the lower deck 202 of the preliminary stack structure 102, lower individual portions of the cell slits 106, replacement gate slits 108, and linear holes 110 (e.g., at the vertical extent, in the Z-direction, of the lower deck 202 and upper portions of the substrate 104) may be formed by removing portions (e.g., via a patterned mask) of the materials of the lower deck 202 of the preliminary stack structure 102 and upper portions of the substrate 104 underlying the cell slits 106, replacement gate slits 108, and linear holes 110, thereby forming voids having respective horizontal profiles (e.g., when viewed from a top-down perspective) of the cell slits 106, replacement gate slits 108, and linear holes 110.

Following formation of the lower portions of the cell slits 106, replacement gate slits 108, and linear holes 110, the lower portions of the cell slits 106, replacement gate slits 108, and linear holes 110 may be filled with a lower deck sacrificial fill. Portions of the formed lower deck sacrificial fill overlying an uppermost surface (e.g., in the Z-direction) of the lower deck 202 may then be removed (e.g., through an abrasive planarization process, such as a CMP process).

Following filling the lower portions of the cell slits 106, replacement gate slits 108, and linear holes 110 with the lower deck sacrificial fill, the upper deck 204 of the preliminary stack structure 102 may be formed over the lower deck 202 of the preliminary stack structure 102 and over the lower deck sacrificial fill within the lower portions of the cell slits 106, replacement gate slits 108, and linear holes 110. The upper deck 204 of the preliminary stack structure 102 may be formed by forming a vertically alternating sequence of the sacrificial material 206 and the insulative material 208 over the lower deck 202 and over the lower deck sacrificial fill within the lower portion of the cell slits 106, replacement gate slits 108, and linear holes 110. Thereafter, the top dielectric material 214 may be formed over the tiers 210 of the sacrificial material 206 and the insulative material 208.

Following formation of the upper deck 204 of the preliminary stack structure 102, the upper portions of the cell slits 106, replacement gate slits 108, and linear holes 110 (e.g., in the upper deck 204) may be formed by removing portions of the materials of the upper deck 204 of the preliminary stack structure 102, thereby forming voids having a horizontal profile (e.g., when viewed from a top-down perspective) of the cell slits 106, replacement gate slits 108, and linear holes 110.

Following formation of the upper portions of the cell slits 106, replacement gate slits 108, and linear holes 110, the lower deck sacrificial fill may be removed from the lower portions of the cell slits 106, replacement gate slits 108, and linear holes 110, thereby resulting in the cell slits 106, replacement gate slits 108, and linear holes 110.

A base oxide material 226 may be formed (e.g., by oxidization of portions of the substrate 104) over exposed portions of the substrate 104 within the cell slits 106, replacement gate slits 108, and linear holes 110 (e.g., lower respective portions, in the Z-direction, of the cell slit sidewalls 218, the replacement gate slit sidewalls 220, and the linear hole sidewalls 222 within the substrate 104). The base oxide material 226 may continuously extend over surfaces of the substrate 104 that form lower (e.g., in the Z-direction) and horizontal (e.g., in the X- and Y-directions and combinations thereof) boundaries of the cell slits 106, replacement gate slits 108, and linear holes 110 below (e.g., in the Z-direction) the preliminary stack structure 102. The base oxide material 226 may be formed of and include dielectric oxide material (e.g., silicon oxide). The base oxide material 226 may be formed following formation of the lower portions of the cell slits 106, replacement gate slits 108, and linear holes 110 in the lower deck 202 of the preliminary stack structure 102, prior to formation of the lower deck sacrificial fill and formation of the upper deck 204 of the preliminary stack structure 102. Alternatively, the base oxide material 226 may be formed following formation of the upper deck 204 of the preliminary stack structure 102 and removal of the lower deck sacrificial fill.

Following formation of the lower deck 202 and the upper deck 204 of the preliminary stack structure 102, a mask material 228 may be formed over exposed surfaces of the microelectronic device structure 100. The mask material 228 may continuously extend over surfaces of the microelectronic device structure 100 defining the cell slits 106, replacement gate slits 108, and linear holes 110. As shown in FIG. 2B, the mask material 228 may substantially cover and continuously extend across the exposed surfaces of the sidewalls 216 (FIG. 2A) within the cell slits 106, replacement gate slits 108, and linear holes 110 (e.g., cell slit sidewalls 218, replacement gate slit sidewalls 220, linear hole sidewalls 222) of the preliminary stack structure 102 and the substrate 104. The mask material 228 may further substantially cover and continuously extend across the exposed surfaces of the base oxide material 226 within the cell slits 106, replacement gate slits 108, and linear holes 110 (e.g., cell slit sidewalls 218, replacement gate slit sidewalls 220, linear hole sidewalls 222 (FIG. 2A)). In some embodiments, the mask material 228 is formed of and includes semiconductor material, such as polysilicon. The mask material 228 may be doped or may be undoped. By way of non-limiting example, the mask material 228 may be formed of and include n-type doped polysilicon. The mask material 228 may be formed to have a desired thickness, such as a thickness within a range of from approximately five (5) nm to approximately fifteen (15) nm, such as approximately ten (10) nm.

Following formation of the mask material 228, a cell slit oxide barrier 230 may be formed over the mask material 228. The cell slit oxide barrier 230 may substantially cover and continuously extend across exposed surfaces of the mask material 228 within the cell slits 106, replacement gate slits 108, and linear holes 110 (e.g., over cell slit sidewalls 218, replacement gate slit sidewalls 220, linear hole sidewalls 222 (FIG. 2A)). The cell slit oxide barrier 230 may be formed of and include dielectric oxide material (e.g., silicon oxide).

Still referring to FIG. 2B, following formation of the cell slit oxide barrier 230, a cell slit sacrificial fill 232 may be formed (e.g., non-conformally deposited) within remaining (e.g., unfilled) portions of the cell slits 106, replacement gate slits 108, and linear holes 110. The cell slit sacrificial fill 232 may be formed over the cell slit oxide barrier 230, and may substantially fill the cell slits 106, replacement gate slits 108, and linear holes 110. The cell slit sacrificial fill 232 may be formed of and include at least one material having a etch selectivity relative to the cell slit oxide barrier 230. In some embodiments, the cell slit sacrificial fill 232 is formed of and includes polysilicon-containing material.

Following formation of the cell slit sacrificial fill 232, portions of the cell slit sacrificial fill 232, cell slit oxide barrier 230, and mask material 228 overlying an uppermost surface (e.g., in the Z-direction) of the preliminary stack structure 102 may then be removed (e.g., through an abrasive planarization process, such as a CMP process), which may leave the top dielectric material 214 of the preliminary stack structure 102 exposed, with the cell slit sacrificial fill 232 having an upper surface (e.g., in the Z-direction) substantially coplanar with upper surfaces of the top dielectric material 214, the mask material 228, and the cell slit oxide barrier 230 as shown in FIG. 2B.

Referring next to FIG. 2C, following formation of the cell slit sacrificial fill 232 and partial removal thereof, a top masking material 234 may be formed over the top dielectric material 214 of the preliminary stack structure 102, the mask material 228, the cell slit oxide barrier 230, and the cell slit sacrificial fill 232. The top masking material 234 may substantially cover and continuously extend across the exposed surfaces of the preliminary stack structure 102 above the upper surfaces (e.g., in the Z-direction) of the top dielectric material 214, the mask material 228, the cell slit oxide barrier 230, and the cell slit sacrificial fill 232. The top masking material 234 may be formed of and include dielectric oxide material (e.g., silicon oxide).

Following formation of the top masking material 234, portions of the top masking material 234 substantially directly over the replacement gate slits 108 and the linear holes 110 may be removed (e.g., exhumed) so that the replacement gate slits 108 and linear holes 110 vertically extend (e.g., in the Z-direction) through the top masking material 234, exposing the cell slit sacrificial fill 232 within the replacement gate slits 108 and linear holes 110. As shown in FIG. 2C, the top masking material 234 may substantially cover the cell slit sacrificial fill 232 within the cell slits 106.

After extending the replacement gate slits 108 and linear holes 110 through the top masking material 234, the cell slit sacrificial fill 232 may be removed (e.g., exhumed) from within the replacement gate slits 108 and the linear holes 110. Substantially all of the cell slit sacrificial fill 232 within the replacement gate slits 108 and linear holes 110 may be removed from the replacement gate slits 108 and linear holes 110, while the top masking material 234 may substantially mitigate (e.g., minimize, prevent) removal of the cell slit sacrificial fill 232 from within the cell slits 106.

Following removal of the cell slit sacrificial fill 232 from within the replacement gate slits 108 and the linear holes 110, portions of the cell slit oxide barrier 230 may be removed (e.g., exhumed) from within the replacement gate slits 108 and the linear holes 110. Alternatively, the cell slit oxide barrier 230 is removed along with removal of the cell slit sacrificial fill 232 (e.g., using a single processing act). Substantially all of the cell slit oxide barrier 230 within the replacement gate slits 108 and linear holes 110 may be removed from the replacement gate slits 108 and linear holes 110, while the top masking material 234 may substantially mitigate (e.g., minimize, prevent) removal of the cell slit oxide barrier 230 from within the cell slits 106.

Following removal of the cell slit oxide barrier 230 from within the replacement gate slits 108 and the linear holes 110, the mask material 228 may be removed (e.g., exhumed) from within the replacement gate slits 108 and the linear holes 110. Alternatively, the mask material 228 is removed along with removal of one or more of the cell slit oxide barrier 230 and the cell slit sacrificial fill 232 (e.g., using a single processing act). Substantially all of the mask material 228 within the replacement gate slits 108 and linear holes 110 may be removed from the replacement gate slits 108 and linear holes 110, while the top masking material 234 may substantially mitigate (e.g., minimize, prevent) removal of the cell slit oxide barrier 230 from within the cell slits 106. Alternatively, the cell slit oxide barrier 230 is removed from the replacement gate slits 108 and linear holes 110 along with removal of the cell slit sacrificial fill 232 (e.g., using a single processing act).

Still referring to FIG. 2C, following removal of the mask material 228 from within the replacement gate slits 108 and the linear holes 110, portions of the sacrificial material 206 of the tiers 210 of the preliminary stack structure 102 may be removed (e.g., trimmed) via the replacement gate slits 108 and the linear holes 110 so as to form sacrificial material trim edges 236 at, proximate, or within horizontal boundaries of the cell slits 106 in the Y-direction. In some embodiments, the sacrificial material trim edges 236 are approximately horizontally aligned, in the Y-direction, with the ends of the long edges, in the Y-direction, of the cell slits 106. As shown in FIG. 2C, portions of the sacrificial material 206 are removed so that the sacrificial material trim edges 236 are individually farther in the Y-direction from corresponding (e.g., nearest) replacement gate slits 108 or linear holes 110 than the respective horizontal ends, in the Y-direction, of adjacent portions of mask material 228 within (e.g., partially filling) individual cell slits 106. As further shown in FIG. 2C, remaining portions of the sacrificial material 206 are interposed, in the X-direction, between the long edges (e.g., extending in the Y-direction) of the mask material 228 within cell slits 106 horizontally neighboring one another in the X-direction. The material removal process (e.g., nitride trim process) to form the sacrificial material trim edges 236 may disrupt the continuity of the sacrificial material 206 within the tiers 210, such that portions of the sacrificial material 206 within an individual tier 210 are discrete from and discontinuous with other portions of the sacrificial material 206 within the same tier 210.

Following removal of the portions of the sacrificial material 206 as depicted in FIG. 2C, a series of trim-oxidation cycles are effectuated to successively form one or more mask material oxide separator structures 238 at the cell slit sidewalls 218 of the preliminary stack structure 102. The resulting mask material oxide separator structures 238 of two (2) such trim-oxidation cycles are depicted in FIG. 2D. Sequential processing acts of one such trim-oxidation cycle are depicted in FIGS. 2E through 2G. The mask material oxide separator structures 238 may be formed between, in the X-direction, the cell slit sidewalls 218 and adjacent portions of the cell slit sacrificial fill 232. The completion of an individual trim-oxidation cycle may result in the formation of one or more individual mask material oxide separator structures 238 at cell slit sidewall 218 of individual cell slits 106. After formation of a first group of the mask material oxide separator structures 238 by way of a first trim-oxidation cycle, a second group of the mask material oxide separator structures 238 may be formed by way of a second trim-oxidation cycle, a third group of the mask material oxide separator structures 238 may be formed by way of a third trim-oxidation cycle, and so on, until the series of trim-oxidation cycles is completed. Neighboring mask material oxide separator structures 238 may form a horizontal pitch, in the Y-direction, with respect to neighboring mask material oxide separator structures 238, which may correspond to a pitch of a later-formed vertical memory string structure 286 (FIG. 2Q). The pitch, in the Y-direction, between horizontally neighboring mask material oxide separator structures 238 may be substantially equivalent to the width, in the Y-direction, of one of the mask material oxide separator structure 238 combined with the width, in the Y-direction, of the space between horizontally neighboring mask material oxide separator structures 238. Later-formed separator structures 276 (FIG. 2Q) may subsequently occupy approximately the same space as the mask material oxide separator structures 238, and later-formed vertical memory string structures 286 (FIG. 2Q) may subsequently occupy the space (e.g., in the Y-direction) between horizontally neighboring separator structures 276.

Within an individual cell slit 106, each subsequent trim-oxidation cycle may form one or more individual mask material oxide separator structures 238 horizontally positioned relatively farther away (e.g., in the Y-direction) from the corresponding (e.g., nearest) replacement gate slit 108 or linear hole 110 than another individual mask material oxide separator structure 238 formed through a previous trim-oxidation cycle.

At the processing stage depicted in FIG. 2D, two (2) individual portions at each opposing end, in the Y-direction, of the sacrificial material 206 of the tiers 210 partially defining individual cell slit sidewalls 218 of the preliminary stack structure 102 have been sequentially removed to expose corresponding portions of the mask material 228. Further, two (2) portions at each opposing end, in the Y-direction, of the mask material 228 at the horizontal boundaries of individual cell slit sidewalls 218 have been sequentially removed to recede corresponding mask material edges 240, in the Y-direction, away from the corresponding (e.g., nearest) replacement gate slit 108 or linear hole 110. Further, two (2) of the mask material oxide separator structures 238 have been formed at each opposing end, in the Y-direction, of the mask material 228 at the horizontal boundaries of individual cell slit sidewalls 218 on the mask material edges 240. Two (2) of the mask material oxide separator structures 238 at each opposing end, in the Y-direction, of the mask material 228 (e.g., four (4) mask material oxide separator structures 238) on one of the cell slit sidewalls 218 of an individual cell slit 106 result from two (2) previous trim-oxidation cycles serially effectuated before the onset of the trim-oxidation cycle described with reference to FIGS. 2E through 2G. In addition, two (2) other of the mask material oxide separator structures 238 at each opposing end, in the Y-direction, of the mask material 228 (e.g., four (4) mask material oxide separator structures 238) on an additional one of the cell slit sidewalls 218 opposing, in the X-direction, the one of the cell slit sidewalls 218 of the cell slit 106 may also result from the two (2) previous trim-oxidation cycles. The widths and/or pitches of individual mask material oxide separator structures 238 may be determined, in part, by a respective horizontal extent, in the Y-direction, of the sacrificial material 206 and/or mask material 228 removed during a respective trim-oxidation cycle, as described in further detail below.

Referring to FIG. 2E, an individual trim-oxidation cycle includes removing portions of the sacrificial material 206 at individual opposing ends, in the Y-direction, of portions of the sacrificial material 206 between the neighboring cell slits 106, in the X-direction, to expose portions of the mask material 228. The material removal process may include exposing the sacrificial material trim edges 236, established during a previous trim-oxidation cycle, to at least one etchant (e.g., hot phosphoric acid etchant). The etchant may be introduced to the sacrificial material trim edges 236 by way of the replacement gate slits 108 and linear holes 110. For individual sacrificial material trim edges 236 that face and are located closer, in the Y-direction, to a replacement gate slit 108 than to a linear hole 110, etchant may be introduced to those sacrificial material trim edges 236 via the nearest replacement gate slit 108. Likewise, for individual sacrificial material trim edges 236 that face and are located closer, in the Y-direction, to one or more linear holes 110 than to a replacement gate slit 108, etchant may be introduced to those sacrificial material trim edges 236 via the one or more linear holes 110. In this manner, the material removal process may be carried out to progressively remove (e.g., trim back) portions of the sacrificial material 206. The horizontal extent, in the Y-direction, of the sacrificial material 206 removed (e.g., trimmed back) may be controlled, as desired, by choosing an etchant composition according to predetermined etching rates, by choosing the duration of the material removal process, and/or by choosing other parameters of the material removal process.

By removing a horizontal extent, in the Y-direction, of the sacrificial material 206, the sacrificial material trim edge 236 may be horizontally receded in the Y-direction to a selected new horizontal position to impart a desired horizontal width, in the Y-direction, of exposed mask material 228. The width in the Y-direction of the exposed mask material 228 may be less than the pitch of a later-formed vertical memory string structure 286 (FIG. 2Q). In one embodiment, the width in the Y-direction of the exposed mask material 228 is less than the combined horizontal extent in the Y-direction of a pitch in the Y-direction of a corresponding later-formed vertical memory string structure 286 (FIG. 2Q) minus a horizontal extent of removal of the sacrificial material 206, which may be slightly greater than the thickness, in the X-direction, of a later-formed mask material oxide separator structure 238.

Referring to FIG. 2F, following removal of the additional portions of the sacrificial material 206, the resulting exposed portions of the mask material 228 may be selectively removed (e.g., via a tetramethylammonium hydroxide (“TMAH”) wet etch operation) to further horizontally recede, in the Y-direction, the individual mask material edges 240 away from the replacement gate slit 108 or linear hole 110 most horizontally proximate thereto in the Y-direction. The mask material edges 240 may additionally be horizontally receded in the Y-direction beyond the adjacent sacrificial material trim edge 236, forming a recess between the cell slit oxide barrier 230 and the sacrificial material 206. The additional material removal process may include subjecting the mask material edges 240 of the mask material 228 established at the processing stage depicted in FIG. 2E to at least one etchant (e.g., hot phosphoric acid etchant). The etchant may be introduced to the mask material edges 240 by way of the replacement gate slits 108 or the linear holes 110 nearest the respective mask material edges 240.

By removing a horizontal extent in the Y-direction of the mask material 228, the mask material edge 240 may be horizontally receded in the Y-direction to a selected new horizontal position to impart a desired horizontal width and/or pitch in the Y-direction of individual later-formed vertical memory string structures 286 (FIG. 2Q). Accordingly, the width and pitch in the Y-direction of later-formed vertical memory string structures 286 (FIG. 2Q) may be controlled, as desired, by choosing an etchant composition according to predetermined etching rates, by choosing the duration of the material removal process, and/or by choosing other parameters of the material removal process. The horizontal extent in the Y-direction of removal of the mask material 228 may be within a range of from about 20 nm to about 100 nm, such as from about 30 nm to about 90 nm, from about 40 nm to about 80 nm, or about 60 nm.

Referring to FIG. 2G, following removal of the additional portions of the mask material 228 and corresponding formation of new mask material edges 240, an individual trim-oxidation cycle includes forming individual mask material oxide separator structures 238 at corresponding individual exposed mask material edges 240 within the cell slits 106. The material formation process of FIG. 2G may result in the formation of a mask material oxide separator structure 238 at a corresponding mask material edge 240 horizontally facing, in the Y-direction, the corresponding replacement gate slit 108 or linear hole 110 that is nearest to the mask material edge 240. In some embodiments, the mask material oxide separator structures 238 are formed of and include dielectric oxide material, such as silicon oxide (e.g., SiO₂). The mask material oxide separator structures 238 may individually span substantially an entire width, in the X-direction, between the cell slit oxide barrier 230 and the cell slit sidewall 218. Further, the mask material oxide separator structures 238 may continuously span substantially an entire combined vertical extent (e.g., in the Z-direction) of the cell slit sidewall 218 of the preliminary stack structure 102 and the substrate 104.

As depicted in FIG. 2G, an individual cell slit 106 may be bounded in the X-direction by two opposing mask material 228 portions, each mask material 228 portion having two mask material edges 240 at opposing ends in the Y-direction thereof. Accordingly, at an individual cell slit 106, an individual trim-oxidation cycle may form two (2) pairs of mask material oxide separator structures 238 (e.g., four (4) mask material oxide separator structures 238). One oxide separator structure 238 of each pair may be on an opposite end, in the Y-direction, of a portion of the mask material 228 from another oxide separator structure 238 of the pair. In addition, an individual oxide separator structure 238 may be substantially horizontally aligned in the Y-direction with another oxide separator structure 238 neighboring the oxide separator structure 238 in the X-direction. For a preliminary stack structure 102 that comprises multiple cell slits 106, each trim-oxidation cycle may result in the formation of four (4) mask material oxide separator structures 238 within each respective cell slit 106.

As shown in FIG. 2G, the trim-oxidation cycle described with reference to FIGS. 2E through 2G may result in the formation of mask material oxide separator structures 238 within individual cell slits 106. Individual mask material oxide separator structures 238 may individually horizontally extend in the X-direction from and between adjacent cell slit oxide barriers 230 and cell slit sidewalls 218. The mask material oxide separator structures 238 may vertically span (e.g., in the Z-direction) substantially the entire height of the cell slit 106, encompassing a vertical span (e.g., in the Z-direction) of both the lower deck 202 and the upper deck 204 of the preliminary stack structure 102 and of the substrate 104.

Following the completion of an individual trim-oxidation cycle, one or more additional trim-oxidation cycle(s) may be effectuated to form additional mask material oxide separator structures 238 at the cell slit sidewalls 218 of the preliminary stack structure 102. Thereafter, additional processing acts similar to those previously described with reference to FIGS. 2E through 2G may be effectuated for the additional trim-oxidation cycle(s).

FIG. 2H depicts an outcome of multiple trim-oxidation cycles to form multiple mask material oxide separator structure 238 at the cell slit sidewalls 218 of the preliminary stack structure 102. For clarity and case of understanding the drawings and associated description, the tiers 210 are omitted from the detail view of FIG. 2H. As shown in FIG. 2H, substantially the entire respective horizontal spans in the Y-direction of the sacrificial material 206 between the cell slits 106 (FIGS. 2C through 2G) and substantially the entire respective portions of mask material 228 at the horizontal peripheries of the cell slits 106 (FIGS. 2C through 2G) have been removed (FIG. 2G). Further, spaced mask material oxide separator structures 238 are positioned along horizontally peripheral portions of the cell slits 106 extending the Y-direction and previously occupied by the mask material 228.

A quantity of mask material oxide separator structures 238 within individual cell slits 106 in the preliminary stack structure 102 may be equal to four times (4×) a quantity of trim-oxidation cycles effectuated. The quantity of mask material oxide separator structures 238 in the preliminary stack structure 102 may be determined, in part, by the horizontal length in the Y-direction of the cell slits 106, the horizontal width in the Y-direction of the mask material oxide separator structures 238, and the horizontal pitch in the Y-direction defined by the horizontal width and spacing of the mask material oxide separator structures 238. The mask material oxide separator structures 238 may each have substantially the same horizontal width and/or spacing as one another, or one or more of the mask material oxide separator structures 238 may have a different horizontal width and/or a different horizontal spacing than one or more other of the mask material oxide separator structures 238. In some embodiments, an individual cell slit 106 has a group of ten (10) of the mask material oxide separator structures 238 formed at each of the two (2) horizontally opposing (e.g., in the X-direction) cell slit sidewalls 218 of the preliminary stack structure 102. In other embodiments, an individual cell slit 106 has nine (9) or fewer mask material oxide separator structures 238 formed at each of the two horizontally opposing cell slit sidewalls 218 of the preliminary stack structure 102. In other embodiments, an individual cell slit 106 has eleven (11) or more mask material oxide separator structures 238 formed at each of the two horizontally opposing cell slit sidewalls 218 of the preliminary stack structure 102.

During individual processing stages of an individual trim-oxidation cycle, multiple cell slits 106 of the preliminary stack structure 102 may be synchronously (e.g., simultaneously) acted upon. By way of non-limiting example, if multiple cell slits 106 are to individually have a group of twenty (20) mask material oxide separator structures 238 formed therein (e.g., ten (10) mask material oxide separator structures 238 per cell slit sidewall 218 defining the individual cell slit 106) during an individual trim-oxidation cycle, four (4) opposing (e.g., in the X-direction) mask material oxide separator structures 238 may be formed with each of the cell slits 106 of the preliminary stack structure 102. Five (5) sequential trim-oxidation cycles may be conducted in this manner, thereby forming twenty (20) of the mask material oxide separator structures 238 within each of the cell slits 106.

Referring next to FIG. 2I, following sequential formation of the mask material oxide separator structures 238 during the series of trim-oxidation cycles, a backfill material 242 may be formed in and over the preliminary stack structure 102, converting the tiers 210 of the preliminary stack structure 102 to tiers 210′ of the preliminary stack structure 102. The backfill material 242 may substantially cover and continuously extend across the sidewalls 216 (e.g., cell slit sidewalls 218, linear hole sidewalls 222, and replacement gate slit sidewalls 220) of the preliminary stack structure 102, including spaces between neighboring mask material oxide separator structures 238 at the cell slit sidewalls 218, and upward-facing (e.g., in the Z-direction) surfaces of the substrate 104 within individual cell slits 106, replacement gate slits 108, and linear holes 110. The backfill material 242 may conform to a topography of an upper surface of the top masking material 234 (FIG. 2H). The backfill material 242 may fill open (e.g., unfilled) spaces between the insulative material 208 of neighboring tiers 210 of the preliminary stack structure 102 that were left void as a result of the trim-nitride cycles previously described with reference to FIGS. 2D through 2H.

The backfill material 242 may be formed of and include at least one material having different etch selectivity than the insulative material 208 and subsequently formed materials (e.g., an additional sacrificial fill 244 (FIG. 2J), a barrier oxide material 254 (FIG. 2N)). The backfill material 242 may be selectively etchable relative to the insulative material 208 during common (e.g., collective, mutual) exposure to a first etchant; and the insulative material 208 may be selectively etchable to the backfill material 242 during common exposure to a second, different etchant. In some embodiments, the backfill material 242 of each of the tiers 210′ of the preliminary stack structure 102 is formed of and includes a dielectric nitride material, such as SiN_{y} (e.g., Si₃N₄). The backfill material 242 may, for example, be selectively etchable relative to the insulative material 208 during common exposure to a wet etchant comprising phosphoric acid (H₃PO₄). In additional embodiments, the backfill material 242 is formed of and includes dielectric nitride material, and an additional material (also referred to herein as a core material) having a different material composition than the dielectric nitride material on or over the dielectric nitride material.

Referring next to FIG. 2J, following formation of the backfill material 242, portions of the backfill material 242 within replacement gate slits 108 and linear holes 110 may be substantially removed from the replacement gate slits 108 and linear holes 110, while substantially remaining in the cell slits 106 and between the insulative material 208 of neighboring tiers 210′ of the preliminary stack structure 102.

Still referring to FIG. 2J, following removal of the backfill material 242 from the replacement gate slits 108 and the linear holes 110, an additional sacrificial fill 244 may be formed (e.g., non-conformally deposited) within the replacement gate slits 108 and the linear holes 110. The additional sacrificial fill 244 may substantially fill the replacement gate slits 108 and linear holes 110. The additional sacrificial fill 244 may be formed of and include at least one material having an etch selectivity relative to the insulative material 208 of the tiers 210′ and the backfill material 242. In some embodiments, the additional sacrificial fill 244 is formed of and includes polysilicon. Following formation of the additional sacrificial fill 244, portions of the additional sacrificial fill 244 overlying an uppermost surface (e.g., in the Z-direction) of the preliminary stack structure 102 may be removed (e.g., through an abrasive planarization process, such as a CMP process). Removal of the additional sacrificial fill 244 may leave the top masking material 234 (FIG. 2H) exposed, with the additional sacrificial fill 244 having an upper surface (e.g., in the Z-direction) substantially coplanar with upper surfaces of the top masking material 234.

Following removal of the upper portions of the additional sacrificial fill 244, the top masking material 234 (FIG. 2H) may be removed, exposing upper surfaces (e.g., in the Z-direction) of the cell slit sacrificial fill 232 and the top dielectric material 214, with the additional sacrificial fill 244 having an upper surface (e.g., in the Z-direction) substantially coplanar with upper surfaces of the cell slit sacrificial fill 232 and top dielectric material 214. Alternatively, the top masking material 234 may be removed along with the removal of the additional sacrificial fill 244 and/or portions of the backfill material 242 (e.g., using a single processing act).

Referring next to FIG. 2K, following removal of the top masking material 234 (FIG. 2H), an additional top masking material 246 may be formed over the top dielectric material 214 of the preliminary stack structure 102, the cell slit oxide barrier 230 (FIG. 2J), the cell slit sacrificial fill 232 (FIG. 2J), and the additional sacrificial fill 244. The additional top masking material 246 may substantially cover and continuously extend across the exposed surfaces of the preliminary stack structure 102 above the upper surfaces (e.g., in the Z-direction) of the top dielectric material 214 of the preliminary stack structure 102, the cell slit oxide barrier 230, the cell slit sacrificial fill 232, and the additional sacrificial fill 244. The additional top masking material 246 may be formed of and include dielectric oxide material (e.g., silicon oxide).

Following formation of the additional top masking material 246, portions of the additional top masking material 246 within horizontal areas of the cell slits 106 may be removed (e.g., exhumed) so that the cell slits 106 vertically extend (e.g., in the Z-direction) through the additional top masking material 246, exposing the cell slit sacrificial fill 232 (FIG. 2J) within the cell slits 106. As shown in FIG. 2K, the additional top masking material 246 may substantially cover the additional sacrificial fill 244 within the replacement gate slits 108 and linear holes 110.

After extending the cell slits 106 through the additional top masking material 246, the cell slit sacrificial fill 232 may be removed (e.g., exhumed) from within the cell slits 106. Substantially all of the cell slit sacrificial fill 232 (FIG. 2J) within the cell slits 106 may be removed from the cell slits 106. The additional top masking material 246 may substantially mitigate (e.g., minimize, prevent) removal of the additional sacrificial fill 244 from within the replacement gate slits 108 and linear holes 110.

Following removal of the cell slit sacrificial fill 232 (FIG. 2J) from within the cell slits 106, portions of the cell slit oxide barrier 230 (FIG. 2J) may be removed (e.g., exhumed) from the cell slit sidewalls 218. Alternatively, the cell slit oxide barrier 230 is removed along with removal of the cell slit sacrificial fill 232 (e.g., using a single processing act). Substantially all of the cell slit oxide barrier 230 within the cell slits 106 may be removed from the cell slits 106. Additionally, portions of the base oxide material 226 may be removed from surfaces of the substrate 104 within the cell slits 106 along with removal of portions of the cell slit oxide barrier 230 (e.g., using a single processing act). As depicted in FIG. 2K, removal of the cell slit sacrificial fill 232 and the cell slit oxide barrier 230 may expose, to the internal volume of the individual cell slits 106, substantially the entire vertical extent (e.g., in the Z-direction) of the mask material oxide separator structures 238. Further, the individual mask material oxide separator structures 238 may be partially horizontally encompassed (e.g., on multiple remaining sides) by the backfill material 242 along substantially their entire vertical extent (e.g., in the Z-direction).

For clarity and ease of understanding the description, the additional top masking material 246 is not illustrated in FIGS. 2L through 2N, but it will be understood that the additional top masking material 246 may be disposed over the top dielectric material 214. Referring to FIG. 2L, following removal of the cell slit oxide barrier 230 from the cell slit sidewalls 218, the mask material oxide separator structures 238 may be removed (e.g., exhumed) from within the cell slits 106, forming corresponding separator recesses in the backfill material 242 at the cell slit sidewalls 218. The individual separator recesses may have a horizontal profile approximately the same size and shape of the corresponding individual removed mask material oxide separator structure 238. In one embodiment, not all of the mask material oxide separator structures 238 are removed; rather, individual horizontal portions (e.g., in the X-direction) of individual mask material oxide separator structures 238 remain along the vertical extent of the individual separator recesses along an individual respective horizontal boundary (e.g., in the X-direction) of the individual separator recesses, the horizontal boundary positioned away (e.g., in the X-direction) from the respective horizontal lateral centers (e.g., along the Y-direction) of the corresponding cell slits 106.

Following removal of the mask material oxide separator structures 238, additional sacrificial material may be formed (e.g., conformally deposited) over the cell slit sidewalls 218 and surfaces of the separator recesses in the backfill material 242 at the cell slit sidewalls 218. The additional sacrificial material may substantially cover and continuously extend across the cell slit sidewalls 218. The additional sacrificial material may conform to a topography of the separator recesses in the backfill material 242 at the cell slit sidewalls 218. In some embodiments, the additional sacrificial material is polysilicon. The additional sacrificial material may be doped or may be undoped. By way of non-limiting example, the additional sacrificial material may be formed of and include n-type doped polysilicon.

Following formation of the additional sacrificial material over the cell slit sidewalls 218, further sacrificial material having etch selectively relative at least to the additional sacrificial material and the backfill material 242 may be formed (e.g., deposited) over the additional sacrificial material and additional surfaces defining the separator recesses in the backfill material 242 at the cell slit sidewalls 218. The further sacrificial material may substantially cover and continuously extend across the additional sacrificial material on the cell slit sidewalls 218. The further sacrificial material may conform to a topography of the separator recesses in the backfill material 242 at the cell slit sidewalls 218. In some embodiments, the further sacrificial material is formed of and includes titanium nitride.

Following formation of the further sacrificial material, portions of the additional sacrificial material and the further sacrificial material may be removed (e.g., exhumed), substantially removing the additional sacrificial material and the further sacrificial material from surfaces of the cell slit sidewalls 218 outside of the separator recesses, and substantially maintaining portions of the additional sacrificial material and the further sacrificial material within the separator recesses in the backfill material 242 at the cell slit sidewalls 218.

Still referring to FIG. 2L, removal of portions of the additional sacrificial material and the further sacrificial material may result in the formation of preliminary separator structures 248 within the separator recesses in the backfill material 242 at the cell slit sidewalls 218. The preliminary separator structures 248 may individually have a horizontal profile approximately the same size and shape of the removed mask material oxide separator structures 238. The preliminary separator structures 248 may vertically span (e.g., in the Z-direction) substantially the entire height of the cell slit 106, encompassing a vertical span (e.g., in the Z-direction) of both the lower deck 202 and the upper deck 204 of the preliminary stack structure 102 and of the substrate 104.

The preliminary separator structures 248 may individually comprise a first preliminary separator sub-structure 250 and a second preliminary separator sub-structure 252. The first preliminary separator sub-structure 250 may be formed of and include the additional sacrificial material (e.g., polysilicon), and may be horizontally adjacent in the X-direction to the backfill material 242 at the cell slit sidewalls 218. The second preliminary separator sub-structure 252 may be formed of and include the further sacrificial material (e.g., titanium nitride), and may be partially horizontally encompassed by the first preliminary separator sub-structure 250.

Referring to FIG. 2M, following formation of the preliminary separator structures 248, portions of the backfill material 242 may be removed (e.g., recessed) horizontally (e.g., in the X-direction, the Y-direction, and combinations thereof). As a result of the removal, horizontal boundaries of the backfill material 242 of the tiers 210′ of the preliminary stack structure 102 may be horizontally offset from the horizontal boundaries of the insulative material 208 of the tiers 210′ of the preliminary stack structure 102. Accordingly, surfaces (e.g., vertically extending surfaces, horizontally extending surfaces) of the insulative material 208 proximate the cell slits 106 and the cell slit sidewalls 218 may be exposed by the removal of the backfill material 242. In one embodiment, the backfill material 242 is recessed to such a horizontal extent (e.g., in the X-direction, the Y-direction, and combinations thereof) that the preliminary separator structures 248 no longer contact the backfill material 242 portions of the tiers 210′ because the removal of the backfill material 242 formed respective horizontal gaps (e.g., in the X-direction, in the Y-direction) between individual preliminary separator structures 248 and the backfill material 242. As shown in FIG. 2M, the preliminary separator structures 248 may individually contact respective portions of the insulative material 208 along the cell slit sidewalls 218.

Referring to FIG. 2N, following removal of portions of the backfill material 242, a barrier oxide material 254 may be formed on or over exposed surfaces of the microelectronic device structure 100. The barrier oxide material 254 may continuously extend over surfaces of the microelectronic device structure 100 defining the cell slits 106. The barrier oxide material 254 may substantially continuously extend across and cover the exposed surfaces (e.g., the cell slit sidewalls 218) of the preliminary stack structure 102 and the substrate 104. The barrier oxide material 254 may conform to a topography of the cell slit sidewalls 218 and exposed surfaces (e.g., horizontally extending surfaces, vertically extending surfaces) of the preliminary separator structures 248. The barrier oxide material 254 may be formed to continuously span substantially an entire combined vertical extent (e.g., in the Z-direction) of the cell slit sidewalls 218. The barrier oxide material 254 may be formed of and include dielectric oxide material (e.g., silicon oxide).

Following formation of the barrier oxide material 254, a storage nitride material 256 may be formed on or over exposed surfaces of the microelectronic device structure 100. The storage nitride material 256 may continuously extend on or over the barrier oxide material 254 inside and outside of the horizontal areas of the cell slits 106. The storage nitride material 256 may conform to a topography of exposed surfaces (e.g., horizontally extending surfaces, vertically extending surfaces) of the barrier oxide material 254. The storage nitride material 256 may be formed to continuously span substantially an entire vertical extent (e.g., in the Z-direction) of the barrier oxide material 254 within the cell slits 106. The storage nitride material 256 may be formed of and include dielectric nitride material (e.g., silicon nitride).

Following formation of the storage nitride material 256, a band engineered tunnel oxide material 258 may be formed on or over exposed surfaces of the microelectronic device structure 100. The band engineered tunnel oxide material 258 may continuously extend on or the storage nitride material 256 inside and outside of the horizontal areas of the cell slits 106. The band engineered tunnel oxide material 258 may conform to a topography of the exposed surfaces (e.g., horizontally extending surfaces, vertically extending surfaces) of the storage nitride material 256. The band engineered tunnel oxide material 258 may be formed to continuously span substantially an entire vertical extent (e.g., in the Z-direction) of the storage nitride material 256 within the cell slits 106. The band engineered tunnel oxide material 258 may be formed of and include a dielectric oxide material (e.g., silicon oxide).

Following formation of the band engineered tunnel oxide material 258, a semiconductor material 260 may be formed on or over exposed surfaces of the microelectronic device structure 100. The semiconductor material 260 may continuously extend on or over the band engineered tunnel oxide material 258 inside and outside of the horizontal areas of the cell slits 106. The semiconductor material 260 may conform to a topography of the exposed surfaces (e.g., horizontally extending surfaces, vertically extending surfaces) of the band engineered tunnel oxide material 258. The semiconductor material 260 may be formed to continuously span substantially an entire vertical extent (e.g., in the Z-direction) of the band engineered tunnel oxide material 258 within the cell slits 106. The semiconductor material 260 may be lightly doped or may be substantially undoped. In some embodiments, the semiconductor material 260 is formed of and includes doped polysilicon, such as N-type polysilicon (e.g., polysilicon doped with one or more N-type conductivity enhancing species, such as one or more of arsenic, phosphorous, and antimony).

The barrier oxide material 254, the storage nitride material 256, the band engineered tunnel oxide material 258, and the semiconductor material 260 may collectively be referred to as the memory cell material 262.

Still referring to FIG. 2N, a memory cell fill 264 may be formed over the semiconductor material 260. The memory cell fill 264 may substantially fill portions of the cell slits 106 remaining unfilled by the preliminary separator structures 248, the barrier oxide material 254, the storage nitride material 256, the band engineered tunnel oxide material 258, and the semiconductor material 260. The memory cell fill 264 may be formed of and include a dielectric material (e.g., dielectric oxide material, such as silicon oxide).

Following formation of the memory cell fill 264, portions of the memory cell fill 264 overlying an uppermost surface (e.g., in the Z-direction) of the preliminary stack structure 102 may be removed (e.g., through an abrasive planarization process, such as a CMP process). Removal of the memory cell fill 264 may likewise remove the additional top masking material 246 and uppermost surfaces (e.g., in the Z-direction) of the top dielectric material 214, the preliminary separator structures 248, the barrier oxide material 254, the storage nitride material 256, the band engineered tunnel oxide material 258, and/or the semiconductor material 260. An upper surface of the memory cell fill 264 may be substantially coplanar with upper surfaces of the top dielectric material 214, the preliminary separator structures 248, the barrier oxide material 254, the storage nitride material 256, the band engineered tunnel oxide material 258, and the semiconductor material 260.

Referring to FIG. 2O, following formation of the memory cell fill 264, the second preliminary separator sub-structures 252 (FIG. 2N) of the preliminary separator structures 248 (FIG. 2N) may be removed (e.g., exhumed). By so doing, modified preliminary separator structures 248′ may be formed from the preliminary separator structures 248. The modified preliminary separator structures 248′ may individually comprise a first preliminary separator sub-structure 250. Substantially the entire vertical extent (e.g., in the Z-direction) of each second preliminary separator sub-structure 252 may be removed, leaving a void adjacent to the first preliminary separator sub-structures 250 and the barrier oxide material 254. The void may define a vertically extending channel within and partially horizontally surrounded by the first preliminary separator sub-structures 250.

Referring to FIG. 2P, following formation of the modified preliminary separator structures 248′, portions of the barrier oxide material 254 and the storage nitride material 256 may be removed (e.g., via a wet etching act). Alternatively, the portions of the barrier oxide material 254 and of the storage nitride material 256 may be removed separately (e.g., using multiple processing acts). The removed portions of the barrier oxide material 254 and the storage nitride material 256 may include individual portions horizontally aligned (e.g., in the Y-direction) with respective modified preliminary separator structures 248′ (FIG. 2O). The removed portions of the barrier oxide material 254 and the storage nitride material 256 may vertically extend (e.g., in the Z-direction) substantially completely through the preliminary stack structure 102 and into the substrate 104.

Following removal of portions of the barrier oxide material 254 and of the storage nitride material 256, the first preliminary separator sub-structures 250 may be exposed to at least one oxidizing agent to form a separator oxide material 266. The process may substantially convert material of the first preliminary separator sub-structure 250 into the separator oxide material 266, and may at least partially (e.g., substantially) fill voids resulting from the removal of the second preliminary separator sub-structure 252 (FIG. 2N), the barrier oxide material 254, and of the storage nitride material 256 with the separator oxide material 266 may be formed over exposed portions of the first preliminary separator sub-structures 250 (FIG. 2O) of the modified preliminary separator structures 248′. Alternatively, a silicon oxide material may be deposited into the voids resulting from the removal of the barrier oxide material 254 and of the storage nitride material 256 to form the separator oxide material 266. In some embodiments, the separator oxide material 266 is formed of and includes a dielectric oxide material, such as silicon oxide (e.g., SiO₂). The separator oxide material 266 may be formed to span substantially the entire vertical extent (e.g., in the Z-direction) of the void formed by removal of the second preliminary separator sub-structure 252 (FIG. 2N).

Following formation of the separator oxide material 266, portions of the band engineered tunnel oxide material 258 may be removed (e.g., via an additional wet etching act). The removed portions of the band engineered tunnel oxide material 258 may include individual portions horizontally overlapping (e.g., horizontally aligned with), in the Y-direction, respective modified preliminary separator structures 248′ (FIG. 2O). The removed portions of the band engineered tunnel oxide material 258 may vertically extend (e.g., in the Z-direction) substantially completely through the preliminary stack structure 102 and into the substrate 104.

Still referring to FIG. 2P, following removal of portions of the band engineered tunnel oxide material 258, exposed portions of the semiconductor material 260 may be exposed to at least one oxidizing agent to form additional separator oxide material 268. The process may substantially convert material of the exposed portions of the semiconductor material 260 into the additional separator oxide material 268, and may at least partially fill voids resulting from the removal of the band engineered tunnel oxide material 258 with the additional separator oxide material 268. Alternatively, a silicon oxide material may be deposited into the voids resulting from the removal of the band engineered tunnel oxide material 258 to form the additional separator oxide material 268. In one embodiment, portions of the band engineered tunnel oxide material 258 may be removed along with removal of portions of the barrier oxide material 254 and the storage nitride material 256 (e.g., using a single processing act), followed by formation of the separator oxide material 266 and the additional separator oxide material 268 during a single processing act. In some embodiments, the additional separator oxide material 268 is formed of and includes a dielectric oxide material, such as silicon oxide (e.g., SiO₂). In additional embodiments, the exposed portions of the semiconductor material 260 may be removed by way of an additional wet etching act following the removal of portions of the band engineered tunnel oxide material 258, and then the additional separator oxide material 268 may be formed (e.g., deposited, grown) within the resulting voids. In further embodiments, portions of the semiconductor material 260 are removed along with removal of portions of the band engineered tunnel oxide material 258 by way of a single processing act, and then the additional separator oxide material 268 may be formed (e.g., deposited, grown) within the resulting voids. The removed portions of the semiconductor material 260 may include individual portions horizontally aligned (e.g., in the Y-direction) with respective preliminary separator structures 248.

The additional separator oxide material 268 may be formed to span substantially the entire vertical extent (e.g., in the Z-direction) of the void formed by removal of the portions of the band engineered tunnel oxide material 258. The additional separator oxide material 268 may have a horizontal extent, in the Y-direction, that spans between remaining portions of semiconductor material 260 and band engineered tunnel oxide material 258. Additionally, the additional separator oxide material 268 may be formed to horizontally span, in the X-direction, part of the void formed by removal of the storage nitride material 256. Individual horizontal separator structure gaps 270 may remain between, in the X-direction, respective portions of the additional separator oxide material 268 and the separator oxide material 266. The separator structure gaps 270 may be horizontally aligned in the Y-direction with respective modified preliminary separator structures 248′ (FIG. 2O). The separator structure gaps 270 may vertically extend substantially completely through the preliminary stack structure 102 and into the substrate 104. By forming the additional separator oxide material 268, separator oxide material 266, and separator structure gap 270, further modified preliminary separator structures 248″ may be formed from the modified preliminary separator structures 248′, the individual further modified preliminary separator structures 248″ comprising an additional separator oxide material 268, separator oxide material 266, and separator structure gap 270.

Following formation of the further modified preliminary separator structures 248″, the top dielectric material 214 (FIG. 2O) may be substantially removed, exposing a top surface 272 (e.g., in the Z-direction) of the backfill material 242. As a result of removing the top dielectric material 214, one or more of the individual further modified preliminary separator structures 248″, the barrier oxide material 254, the storage nitride material 256, the band engineered tunnel oxide material 258, the semiconductor material 260, and the additional sacrificial fill 244 may have respective upper surfaces (e.g., in the Z-direction) that extend above (e.g., in the Z-direction) upper surfaces of the top surface 272 of the backfill material 242.

Referring FIG. 2Q, a separator structure gap fill 274 may be formed within the separator structure gaps 270 (FIG. 2P) of the further modified preliminary separator structures 248″ (FIG. 2P). The separator structure gap fill 274 may substantially fill the separator structure gaps 270. As such, the separator structure gap fill 274 may horizontally span between (e.g., in the X-direction) respective portions of the additional separator oxide material 268 and the separator oxide material 266. Further, the separator structure gap fill 274 may horizontally span between (e.g., in the Y-direction) respective portions of the storage nitride material 256. The separator structure gap fill 274 may vertically span (e.g., in the Z-direction) substantially the entire combined vertical extent (e.g., in the Z-direction) of the preliminary stack structure 102 and the substrate 104. The separator structure gap fill 274 may be formed of and include a dielectric material (e.g., dielectric oxide material, such as silicon oxide). By forming the separator structure gap fill 274, separator structures 276 may be formed from the further modified preliminary separator structures 248″, the separator structures 276 individually comprising the additional separator oxide material 268, separator oxide material 266, and separator structure gap fill 274.

Following formation of the separator structures 276, a dielectric cover 278 may be formed over the top surface 272 of the backfill material 242 (FIG. 2P) of the preliminary stack structure 102 and additionally over the individual separator structures 276, the barrier oxide material 254, the storage nitride material 256, the band engineered tunnel oxide material 258, the semiconductor material 260, and the additional sacrificial fill 244 (FIG. 2P). The dielectric cover 278 may substantially cover and continuously extend across the exposed surfaces of the preliminary stack structure 102 above the upper surfaces (e.g., in the Z-direction) of the top surface 272 of the backfill material 242, the individual separator structures 276, the barrier oxide material 254, the storage nitride material 256, the band engineered tunnel oxide material 258, the semiconductor material 260, and the additional sacrificial fill 244. The dielectric cover 278 may be formed of and include dielectric oxide material (e.g., silicon oxide).

Following formation of the dielectric cover 278, portions of the dielectric cover 278 vertically overlying and within horizontal areas of the replacement gate slits 108 and the linear holes 110 may be removed (e.g., exhumed) to expose the additional sacrificial fill 244 (FIG. 2P) within the replacement gate slits 108 and linear holes 110.

After exposing the additional sacrificial fill 244 (FIG. 2P), the additional sacrificial fill 244 may be removed (e.g., exhumed) from within the replacement gate slits 108 and the linear holes 110. Substantially all of the additional sacrificial fill 244 within the replacement gate slits 108 and linear holes 110 may be removed, while the dielectric cover 278 may substantially mitigate (e.g., minimize, prevent) removal of the memory cell fill 264 from within the cell slits 106.

Following removal of the additional sacrificial fill 244, the microelectronic device structure 100 may be subjected to replacement gate processing. The replacement gate processing may at least partially (e.g., substantially) replace the backfill material 242 (FIG. 2P) of the tiers 210′ of the preliminary stack structure 102 with conductive material 280. By so doing, the replacement gate processing may convert the preliminary stack structure 102 (FIG. 2P) into a stack structure 282. The stack structure 282 may include a vertically alternating (e.g., in the Z-direction) sequence of the insulative material 208 and the conductive material 280 arranged in tiers 210″.

The conductive material 280 of the tiers 210″ of the stack structure 282 may be formed of and include one or more of at least one metal, at least one alloy, at least one conductive metal-containing material (e.g., at last one conductive metal nitride, at least one conductive metal silicide, at least one conductive metal carbide, at least one conductive metal oxide), and at least one conductively doped semiconductor material (e.g., conductively doped polysilicon). In some embodiments, the conductive material 280 is formed of and includes W. Optionally, at least one liner material (e.g., at least one insulative liner material, at least one conductive liner materials) may be formed around the conductive material 280. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive material 280. In some embodiments, the liner material comprises titanium nitride (TiNₓ, such as TiN). In further embodiments, the liner material further includes aluminum oxide (AlOₓ, such as Al₂O₃). As a non-limiting example, for each of the tiers 210″ of the stack structure 282, AlOₓ (e.g., Al₂O₃) may be formed directly adjacent the insulative material 208, TiNₓ (e.g., TiN) may be formed directly adjacent the AlOₓ, and W may be formed directly adjacent the TiNₓ. For clarity and case of understanding the description, the liner material is not illustrated in FIG. 2Q, but it will be understood that the liner material may be disposed around the conductive material 280.

With reference to FIGS. 2P and 2Q, the replacement gate processing employed to form the stack structure 282 may include treating the microelectronic device structure 100 with at least one wet etchant formulated to selectively remove portions of the backfill material 242 of the tiers 210′ of the preliminary stack structure 102 through the replacement gate slits 108 and/or the linear holes 110. The wet etchant may be selected to remove the portions of the backfill material 242 without substantially removing portions of the insulative material 208 of the tiers 210′ of the preliminary stack structure 102, and without substantially removing portions of the barrier oxide material 254, the dielectric cover 278, and the base oxide material 226. In some embodiments wherein the backfill material 242 comprises a dielectric nitride material (e.g., SiN_{y}, such as Si₃N₄) and the insulative material 208 comprises a dielectric oxide material (e.g., SiOₓ, such as SiO₂), the backfill material 242 of the tiers 210′ of the preliminary stack structure 102 may be selectively removed using a wet etchant comprising H₃PO₄. Following the selective removal of the portions of the backfill material 242, the resulting recesses may be filled with the conductive material 280 to form the stack structure 282 (including the tiers 210″ thereof). Following the formation of the stack structure 282, the replacement gate slits 108 may be filled with dielectric material (e.g., dielectric oxide material, such as silicon oxide), thereby forming a filled trench structure. The filled trench structures may horizontally extend (e.g., in the X-direction) substantially perpendicular to the horizontal relatively long edge of the cell slits 106. The linear holes 110 may additionally be filled with dielectric material (e.g., dielectric oxide material, such as silicon oxide).

Referring to FIG. 2Q, the stack structure 282 includes vertical memory cells 284 located at intersections of the memory cell material 262 and conductive materials 280 of the tiers 210″. Multiple vertical memory cells 284 in horizontal alignment (e.g., in the X- and Y-directions) make up an individual vertical memory string structure 286. Individual vertical memory string structures 286 may vertically span substantially the entire vertical extent (e.g., in the Z-direction) of the stack structure 282. Some of the conductive materials 280 may by employed as access line structures (e.g., word line structures) for the vertical memory cells 284. One or more of the lowermost tiers 210″ (e.g., in the Z-direction) of the stack structure 282 may be employed as first select gate structures (e.g., select gate source (SGS) structure(s)), and one or more of the uppermost tiers 210″ (e.g., in the Z-direction) may be employed as second select gate structures (e.g., select gate drain (SGD) structure(s)).

The stack structure 282 of the microelectronic device structure 100 may be divided (e.g., segmented, partitioned) into blocks 288 separated from one another (e.g., in the Y-direction) by the filled trench structures (e.g., the filled replacement gate slits 108). The filled trench structures may individually vertically extend (e.g., in the Z-direction) completely through the stack structure 282.

At least some of the blocks 288 of the stack structure 282 may horizontally extend substantially in parallel in the X-direction. Each of the blocks 288 of the stack structure 282 may exhibit substantially the same geometric configuration (e.g., substantially the same dimensions and substantially the same shape) as each other of the blocks 288, or one or more of the blocks 288 may exhibit a different geometric configuration (e.g., one or more different dimensions and/or a different shape) than one or more other of the blocks 288. In addition, each pair of horizontally neighboring blocks 288 of the stack structure 282 may be horizontally separated from one another by substantially the same distance (e.g., corresponding to a width in the Y-direction of individual replacement gate slits 108) as each other pair of horizontally neighboring blocks 288 of the stack structure 282, or at least one pair of horizontally neighboring blocks 288 of the stack structure 282 may be horizontally separated from one another by a different distance than that separating at least one other pair of horizontally neighboring blocks 288 of the stack structure 282. In some embodiments, the blocks 288 of the stack structure 282 are substantially uniformly (e.g., substantially non-variably, substantially equally, substantially consistently) sized, shaped, and spaced relative to one another.

The individual blocks 288 may be further subdivided into sub-blocks 290, an individual sub-block 290 being defined by the horizontal profile of a corresponding cell slit 106. Thus, a sub-block 290 may include the vertical memory string structures 286 on two (2) opposing (e.g., in the X-direction) cell slit sidewalls 218 of the stack structure 282.

Thus, in accordance with embodiments of the disclosure, a method of forming a microelectronic device includes: forming a preliminary stack structure over a base structure, forming a cell slit vertically extending through the preliminary stack structure, forming an oxide separator structure, forming a sacrificial backfill, removing the oxide separator structure to form a separator recess, forming a preliminary separator structure in the separator recess, forming memory cell material, forming a separator structure to form vertical memory string structures, and replacing the sacrificial backfill with conductive material. The preliminary stack structure comprises tiers. Each tier includes a sacrificial material and an insulative material vertically neighboring the sacrificial material. The cell slit is partially defined by sidewalls of the preliminary stack structure. The oxide separator structure is formed horizontally adjacent to the cell slit. The oxide separator structure vertically extends through the preliminary stack structure. The sacrificial backfill is formed over exposed surfaces of each of the oxide separator structure, the sidewalls of the preliminary stack structure, and the insulative material of the tiers. The memory cell material is formed within the cell slit over the preliminary separator structure and the sidewalls of the preliminary stack structure. The separator structure is formed from the preliminary separator structure. The vertical memory string structures vertically extend through the preliminary stack structure. The vertical memory string structures are horizontally separated from one another by the separator structure. The sacrificial backfill is replaced with conductive material after forming the vertical memory string structures.

In accordance with other embodiments of the disclosure, a microelectronic device includes a stack structure and filled slot structures. The stack structure includes tiers. Each tier includes conductive material vertically neighboring insulative material. The stack structure is divided into blocks horizontally extending in parallel in a first direction and separated from one another in a second direction. The second direction is orthogonal to the first direction. At least one of the blocks includes filled cell slits, separator structures, and vertical memory string structures. The filled cell slits vertically extend completely through the tiers of the stack structure. The filled cell slits are individually defined by two sidewalls of the stack structure horizontally extending in the first second direction. The separator structures vertically extend through the tiers. The separator structures are positioned at and around outer horizontal boundaries of the filled cell slits. The separator structures are horizontally spaced from one another. The separator structures individually comprise dielectric oxide vertically extending completely through the tiers of the stack structure. The vertical memory string structures are positioned at and around the outer horizontal boundaries of the filled cell slits. The vertical memory string structures horizontally alternate with the separator structures. The vertical memory string structures comprise semiconductor material. The semiconductor material vertically extends completely through the tiers of the stack structure. The filled slot structures horizontally alternate with the blocks of the stack structure in the second direction. The filled slot structures vertically extend completely through stack structure.

In accordance with yet other embodiments of the disclosure, a memory device has a stack structure and dielectric-filled trenches. The stack structure includes blocks horizontally extending in parallel in a first direction. The blocks individually include tiers. Each tier has conductive material and insulative material vertically neighboring the conductive material. The blocks individually include a filled cell slit. The filled cell slit vertically extends through the tiers. The filled cell slit comprises memory string structures and dielectric oxide separator structures. The memory string structures vertically extend through all of the tiers. The memory string structures individually include dielectric oxide material, dielectric nitride material, additional dielectric oxide material, and semiconductor material. The dielectric oxide material is inwardly horizontally adjacent to the conductive material of the tiers. The dielectric nitride material is inwardly horizontally adjacent to the dielectric oxide material. The additional dielectric oxide material is inwardly horizontally adjacent to the dielectric nitride material. The semiconductor material is inwardly horizontally adjacent to the additional dielectric oxide material. The dielectric oxide separator structures vertically extend through all of the tiers. The dielectric oxide separator structures individually horizontally extend from and between pairs of the memory string structures. The memory string structures horizontally neighbor one another in a second direction. The second direction is orthogonal to the first direction. The dielectric-filled trenches vertically extend completely through the stack structure. The dielectric-filled trenches horizontal alternate with the blocks in the second direction.

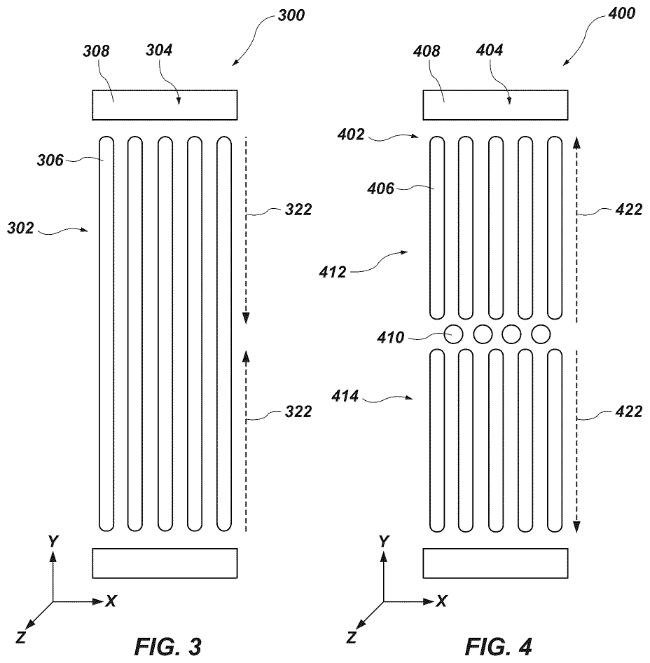

While FIGS. 1 and 2A through 2Q depict a configuration of the cell slits 106, replacement gate slits 108, and linear holes 110 according to embodiments of the disclosure, in additional embodiments the microelectronic device structure 100 are formed to have different configurations of cell slits 106, replacement gate slits 108, and/or linear holes 110. Non-limiting examples of such different profile slot configurations are described in further detail below with reference to FIGS. 3 through 6. As shown in FIGS. 3 through 6, microelectronic device structures 300, 400, 500, 600 may be formed to have cell slits 306, 406, 506, and 606, respectively, which may have different horizontal profiles (e.g., as viewed from a top-down perspective) than that of the cell slits 106 of the microelectronic device structure 100. Likewise, microelectronic device structures 300, 400, 500, 600 may be formed to have replacement gate slits 308, 408, 508, 608, respectively, each of which may have a similar horizontal profile and/or relative position (e.g., as viewed from a top-down perspective) to that of the replacement gate slits 108 of the microelectronic device structure 100. Further, microelectronic device structures 400, 500 may be formed to have linear holes 410, 510, respectively, each of which may have different relative positions (e.g., as viewed from a top-down perspective) than that of the linear holes 110 of the microelectronic device structure 100. While the microelectronic device structures 300, 400, 500, 600 may respectively have different configurations of cell slits 306, 406, 506, and 606, replacement gate slits 308, 408, 508, 608, and/or linear holes 410, 510 than that of the microelectronic device structure 100, microelectronic device structures 300, 400, 500, 600 may be subject to processing stages similar to those previously described with reference to FIGS. 2A through 2Q to form a desirable microelectronic devices of the disclosure.

Referring to FIG. 3, a preliminary stack structure 302 (e.g., corresponding to the preliminary stack structure 102 (FIGS. 1 and 2A through 2P)) of the microelectronic device structure 300 may be formed over a substrate 304. The microelectronic device structure 300 may include one or more cell slits 306 and replacement gate slits 308 therein. The cell slits 306 and the replacement gate slits 308 may define voids vertically extending through the preliminary stack structure 302. As shown in FIG. 3, the cell slits 306 may include multiple, substantially linear voids in the preliminary stack structure 302. An individual cell slit 306 may include a relatively long edge (e.g., horizontal boundary) horizontally extending in the Y-direction and a relatively short edge horizontally extending in the X-direction. The cell slits 306 may individually exhibit a single, oblong horizontal cross-sectional shape (e.g., an obround horizontal cross-sectional shape). Multiple cell slits 306 horizontally aligned with one another in the Y-direction may be horizontally offset from one another in the X-direction.

The replacement gate slits 308 may individually comprise voids (e.g., trenches) vertically extending through the preliminary stack structure 302 and having an elongate horizontal cross-sectional shape (e.g., a substantially rectangular horizontal cross-sectional shape). Individual replacement gate slits 308 may comprise a relatively long edge horizontally extending in the X-direction and a relatively short edge horizontally extending in the Y-direction. Neighboring replacement gate slits 308 may be individually horizontally spaced from one another in the Y-direction, with the row of cell slits 306 disposed therebetween.

The cell slits 306 may have a function similar to that of the cell slits 106 described with reference to FIGS. 1 and 2A through 2Q. The replacement gate slits 308 may have functions similar to those of the replacement gate slits 108 and/or linear holes 110 previously described with reference to FIGS. 1 and 2A through 2Q. As shown in FIG. 3, the microelectronic device structure 300 does not include linear holes (e.g., linear holes 110 described with reference to FIGS. 1 and 2A through 2Q).

Following the formation of the cell slits 306 and replacement gate slits 308, the microelectronic device structure 300 may be subjected to additional processing substantially similar to that previously described with reference to FIGS. 2A through 2Q for the microelectronic device structure 100. Subsequent trim-oxidation cycles (e.g., similar to those previously described with reference to FIGS. 2D through 2G) employed during the additional processing may follow general horizontal directions 322 (e.g., in the Y-direction) away from the replacement gate slits 308. Such trim-oxidation cycles may be effectuated via the replacement gate slits 308 to access the sacrificial material within the tiers of the preliminary stack structure 302.

Further, the microelectronic device structure 300 may be subject to replacement gate processing, similar to the replacement gate processing described above with reference to FIG. 2Q, to convert the preliminary stack structure 302 to a stack structure similar to the stack structure 282 (FIG. 2Q). As a result of the replacement gate processing, the microelectronic device structure 300 may comprise a stack structure that includes a vertically alternating (e.g., in the Z-direction) sequence of insulative material and conductive material arranged in tiers. The replacement gate processing may be carried out on the preliminary stack structure 302 through the replacement gate slits 308, similar to the replacement gate processing described above regarding the replacement gate slits 108 and linear holes 110.

Referring to FIG. 4, a preliminary stack structure 402 (e.g., corresponding to the preliminary stack structure 102 (FIGS. 1 and 2A through 2P)) of the microelectronic device structure 400 may be formed over a substrate 404. The microelectronic device structure 400 may include one or more cell slits 406, replacement gate slits 408, and linear holes 410 therein. The cell slits 406, the replacement gate slits 408, and the linear holes 410 may define voids vertically extending through the preliminary stack structure 402. As shown in FIG. 4, the cell slits 406 may include multiple, substantially linear voids in the preliminary stack structure 402. An individual cell slit 406 may include a relatively long edge (e.g., horizontal boundary) horizontally extending in the Y-direction and a relatively short edge horizontally extending in the X-direction. The cell slits 406 may individually exhibit a single, oblong horizontal cross-sectional shape (e.g., an obround horizontal cross-sectional shape). Multiple cell slits 406 horizontally aligned with one another in the Y-direction may be horizontally offset from one another in the X-direction. In addition, cell slits 406 horizontally aligned with one another in the Y-direction may form sets of cell slits 406, such as a first set 412 of the cell slits 406 and a second set 414 of the cell slits 406. The first set 412 and the second set 414 of the cell slits 406 may be horizontally offset from one another in the Y-direction. As depicted in FIG. 4, individual cell slits 406 of the first set 412 of the cell slits 406 and the second set 414 of the cell slits 406 may have approximately the same respective lengths in the Y-direction as one another, or may have different lengths than one another.

The replacement gate slits 408 may individually comprise voids (e.g., trenches) vertically extending through the preliminary stack structure 402 and having an elongate horizontal cross-sectional shape (e.g., a substantially rectangular horizontal cross-sectional shape). Individual replacement gate slits 408 may comprise a relatively long edge horizontally extending in the X-direction and a relatively short edge horizontally extending in the Y-direction. Neighboring replacement gate slits 408 may be individually horizontally spaced from one another in the Y-direction, with the sets of cell slits 406 (e.g., the first set 412 of cell slits 406, the second set 414 of cell slits 406) and the linear holes 410 disposed therebetween.

As also shown in FIG. 4, the linear holes 410 may individually comprise voids vertically extending through the preliminary stack structure 402 and having a generally circular cross-sectional shape. Multiple linear holes 410 substantially horizontally aligned in the Y-direction may be horizontally offset from one another in the X-direction. The linear holes 410 may be positioned horizontally between (e.g., in the Y-direction) the first set 412 of the cell slits 406 and the second set 414 of the cell slits 406. Additionally, the linear holes 410 may be individually positioned horizontally between, in the X-direction, two (2) corresponding neighboring cell slits 406 of the first set 412 of the cell slits 406 and two (2) corresponding neighboring cell slits 406 of the second set 414 of the cell slits 406. An individual linear hole 410 may be positioned proximate to four (4) cell slits 406. In some embodiments, an individual linear hole 410 is substantially horizontally centered in the X-direction and the Y-direction between the four (4) cell slits 406 most horizontally proximate thereto. The linear hole 410 may be equidistant from each of the four (4) cell slits 406.

The cell slits 406 may have a function similar to that of the cell slits 106 described with reference to FIGS. 1 and 2A through 2Q. The replacement gate slits 408 and linear holes 410 may have functions similar to those of the replacement gate slits 108 and/or linear holes 110 previously described with reference to FIGS. 1 and 2A through 2Q.

Following the formation of the cell slits 406, replacement gate slits 408, and linear holes 410, the microelectronic device structure 400 may be subjected to additional processing substantially similar to that previously described with reference to FIGS. 2A through 2Q for the microelectronic device structure 100. Subsequent trim-oxidation cycles (e.g., similar to those previously described with reference to FIGS. 2D through 2G) employed during the additional processing may follow general horizontal directions 422 away from the linear holes 410, but not, similar to that described with reference to FIGS. 2D through 2G, away from the replacement gate slits 408. Such trim-oxidation cycles may be effectuated via the linear holes 410 to access the sacrificial material within the tiers of the preliminary stack structure 402. A cover material over the individual replacement gate slits 408 and/or a sacrificial fill in the individual replacement gate slits 408 may be provided prior to subjecting the microelectronic device structure 400 to the trim-oxidation cycles (e.g., similar to the processing steps previously described with reference to FIGS. 2D through 2G) in order to effectuate the trim-oxidation cycles via only the linear holes 410 but not the replacement gate slits 408.

Further, the microelectronic device structure 400 may be subject to replacement gate processing, similar to the replacement gate processing described above with reference to FIG. 2Q, to convert the preliminary stack structure 402 to a stack structure similar to the stack structure 282 (FIG. 2Q). As a result of the replacement gate processing, the microelectronic device structure 400 may comprise a stack structure that includes a vertically alternating (e.g., in the Z-direction) sequence of insulative material and conductive material arranged in tiers. The replacement gate processing may be carried out on the preliminary stack structure 402 through the replacement gate slits 408 and linear holes 410, similar to the replacement gate processing described above regarding the replacement gate slits 108 and linear holes 110.

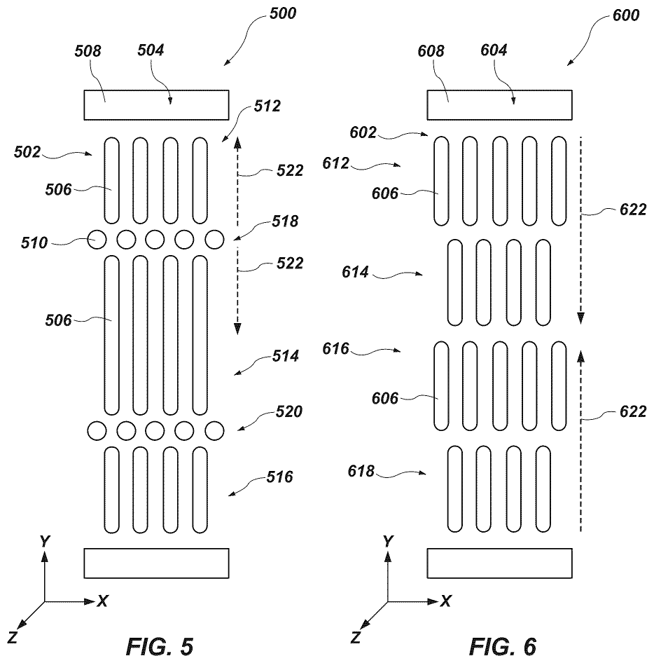

Referring to FIG. 5, a preliminary stack structure 502 (e.g., corresponding to the preliminary stack structure 102 (FIGS. 1 and 2A through 2P)) of the microelectronic device structure 500 may be formed over a substrate 504. The microelectronic device structure 500 may include one or more cell slits 506, replacement gate slits 508, and linear holes 510. The cell slits 506, the replacement gate slits 508, and the linear holes 510 may define voids vertically extending through the preliminary stack structure 502. As shown in FIG. 5, the cell slits 506 may include multiple, substantially linear voids in the preliminary stack structure 502. An individual cell slit 506 may include a relatively long edge (e.g., horizontal boundary) horizontally extending in the Y-direction and a relatively short edge horizontally extending in the X-direction. The cell slits 506 may individually exhibit a single, oblong horizontal cross-sectional shape (e.g., an obround horizontal cross-sectional shape). Multiple cell slits 506 horizontally aligned with one another in the Y-direction may be horizontally offset from one other in the X-direction. In addition, cell slit 506 horizontally aligned with one another in the Y-direction may form sets of cell slits 506, such as a first set 512 of the cell slits 506, a second set 514 of the cell slits 506, and a third set of the cell slits 506. The first set 512 of the cell slits 506, the second set 514 of the cell slits 506, and the third set 516 of the cell slits 506 may be horizontally offset from one another in the Y-direction. Individual cell slits 506 of the first set 512 of the cell slits 506, the second set 514 of the cell slits 506, and/or the third set 516 of the cell slits 506 may have different respective lengths in the Y-direction from one another. As depicted in FIG. 5, individual cell slits 506 of the first set 512 of the cell slits 506 and of the third set 516 of the cell slits 506 have respective lengths in the Y-direction that are less than the respective lengths of individual cell slits 506 of the second set 514 of the cell slits 506. In one embodiment, individual cell slits 506 of the second set 514 of the cell slits 506 have respective lengths in the Y-direction approximately double that of individual cell slits 506 of the first set 512 of the cell slits 506 and the third set 516 of the cell slits 506. Individual cell slits 506 of the first set 512 of the cell slits 506 and the third set 516 of the cell slits 506 may have approximately the same respective lengths in the Y-direction as one another, or may have different lengths than one another.

The replacement gate slits 508 may individually comprise voids (e.g., trenches) vertically extending through the preliminary stack structure 502 and having an elongate horizontal cross-sectional shape (e.g., a substantially rectangular horizontal cross-sectional shape). Individual replacement gate slits 508 may comprise a relatively long edge horizontally extending in the X-direction and a relatively short edge horizontally extending in the Y-direction. Neighboring replacement gate slits 508 may be individually horizontally spaced from one another in the Y-direction, with the sets of cell slits 506 (e.g., the first set 512 of the cell slits 506, the second set 514 of the cell slits 506, and the third set 516 of the cell slits 506) and multiple linear holes 510 disposed therebetween.

As also shown in FIG. 5, the linear holes 510 may individually comprise voids vertically extending through the preliminary stack structure 502 and having a generally circular cross-sectional shape. Multiple linear holes 510 substantially horizontally aligned in the Y-direction may be horizontally offset from one another in the X-direction. In addition, linear holes 510 horizontally aligned with one another in the Y-direction may form sets of linear holes 510, such as a first set 518 of the linear holes 510 and a second set 520 of the linear holes 510. The first set 518 of the linear holes 510 and the second set 520 of the linear holes 510 may be horizontally offset from one another in the Y-direction. The first set 518 of the linear holes 510 may be positioned horizontally between, in the Y-direction, the first set 512 of the cell slits 506 and the second set 514 of the cell slits 506. Likewise, the second set 520 of the linear holes 510 may be positioned horizontally between, in the Y-direction, the second set 514 of the cell slits 506 and the third set 516 of the cell slits 506. Additionally, the linear holes 510 of the first set 518 of the linear holes 510 may be individually positioned horizontally between, in the X-direction, two (2) corresponding neighboring cell slits 506 of the first set 512 of the cell slits 506 and two (2) corresponding neighboring cell slits 506 of the second set 514 of the cell slits 506. Similarly, the linear holes 510 of the second set 520 of the linear holes 510 may be individually positioned horizontally between, in the X-direction, two (2) corresponding neighboring cell slits 506 of the second set 514 of the cell slits 506 and two (2) corresponding neighboring cell slits 506 of the third set 516 of the cell slits 506. An individual linear hole 510 may be positioned proximate to four (4) cell slits 506. In some embodiments, an individual linear hole 510 is substantially horizontally centered in the X-direction and the Y-direction between the four (4) cell slits 506 most horizontally proximate thereto. The linear hole 510 may be equidistant from each of the four (4) cell slits 506.

The cell slits 506 may have a function similar to that of the cell slits 106 described with reference to FIGS. 1 and 2A through 2Q. The replacement gate slits 508 and linear holes 510 may have functions similar to those of the replacement gate slits 108 and/or linear holes 110 previously described with reference to FIGS. 1 and 2A through 2Q.

Following the formation of the cell slits 506, replacement gate slits 508, and linear holes 510, the microelectronic device structure 500 may be subjected to additional processing substantially similar to that previously described with reference to FIGS. 2A through 2Q for the microelectronic device structure 100. Subsequent trim-oxidation cycles (e.g., similar to those previously described with reference to FIGS. 2D through 2G) employed during the additional processing may follow general horizontal directions 522 away from the linear holes 510, but not, similar to that described with reference to FIGS. 2D through 2G, away from the replacement gate slits 508. Such trim-oxidation cycles may be effectuated via the linear holes 510 to access the sacrificial material within the tiers of the preliminary stack structure 502. A cover material over the individual replacement gate slits 508 and/or a sacrificial fill in the individual replacement gate slits 508 may be provided prior to subjecting the microelectronic device structure 500 to the trim-oxidation cycles (e.g., similar to the processing steps previously described with reference to FIGS. 2D through 2G) in order to effectuate the trim-oxidation cycles via only the linear holes 510 but not the replacement gate slits 508.

Further, the microelectronic device structure 500 may be subject to replacement gate processing, similar to the replacement gate processing described above with reference to FIG. 2Q, to convert the preliminary stack structure 502 to a stack structure similar to the stack structure 282 (FIG. 2Q). As a result of the replacement gate processing, the microelectronic device structure 500 may comprise a stack structure that includes a vertically alternating (e.g., in the Z-direction) sequence of insulative material and conductive material arranged in tiers. The replacement gate processing may be carried out on the preliminary stack structure 502 through the replacement gate slits 508 and linear holes 510, similar to the replacement gate processing described above regarding the replacement gate slits 108 and linear holes 110.

Referring to FIG. 6, a preliminary stack structure 602 (e.g., corresponding to the preliminary stack structure 102 (FIGS. 1 and 2A through 2P)) of the microelectronic device structure 600 may be formed over a substrate 604. The microelectronic device structure 600 may include one or more cell slits 606 and replacement gate slits 608 therein. The cell slits 606 and the replacement gate slits 608 may define voids vertically extending through the preliminary stack structure 602. As shown in FIG. 6, the cell slits 606 may include multiple, substantially linear voids in the preliminary stack structure 602. An individual cell slit 606 may include a relatively long edge (e.g., horizontal boundary) horizontally extending in the Y-direction and a relatively short edge horizontally extending in the X-direction. The cell slits 606 may individually exhibit a single, oblong horizontal cross-sectional shape (e.g., an obround horizontal cross-sectional shape). Multiple cell slits 606 horizontally aligned with one another in the Y-direction may be horizontally offset from one another in the X-direction. In addition, cell slits 406 horizontally aligned with one another in the Y-direction may form sets of cell slits 606, such as a first set 612 of cell slits 606, a second set 614 of cell slits 606, a third set 616 of cell slits 606, and a fourth set 618 of cell slits 606. The first set 612 of cell slits 606, the second set 614 of cell slits 606, the third set 616 of cell slits 606, and the fourth set 618 of cell slits 606 may be horizontally offset from one another in the Y-direction. As depicted in FIG. 6, individual cell slits 606 of the first set 612 of cell slits 606, the second set 614 of cell slits 606, the third set 616 of cell slits 606, and the fourth set 618 of cell slits 606 may have approximately the same respective lengths in the Y-direction as one another, or may have different lengths than one another.

The replacement gate slits 608 may individually comprise voids (e.g., trenches) vertically extending through the preliminary stack structure 602 and having an elongate horizontal cross-sectional shape (e.g., a substantially rectangular horizontal cross-sectional shape). Individual replacement gate slits 608 may comprise a relatively long edge horizontally extending in the X-direction and a relatively short edge horizontally extending in the Y-direction. Neighboring replacement gate slits 608 may be individually horizontally spaced from one another in the Y-direction, with the sets of cell slits 606 (e.g., the first set 612 of cell slits 606, the second set 614 of cell slits 606, the third set 616 of cell slits 606, and the fourth set 618 of cell slits 606) disposed therebetween.

The cell slits 606 may have a function similar to that of the cell slits 106 described with reference to FIGS. 1 and 2A through 2Q. The replacement gate slits 608 may have functions similar to those of the replacement gate slits 108 and/or linear holes 110 previously described with reference to FIGS. 1 and 2A through 2Q. As shown in FIG. 6, the microelectronic device structure 600 does not include linear holes (e.g., linear holes 110 described with reference to FIGS. 1 and 2A through 2Q).

Following the formation of the cell slits 606 and replacement gate slits 608, the microelectronic device structure 600 may be subjected to additional processing substantially similar to that previously described with reference to FIGS. 2A through 2Q for the microelectronic device structure 100. Subsequent trim-oxidation cycles (e.g., similar to those previously described with reference to FIGS. 2D through 2G) employed during the additional processing may follow general horizontal directions 622 away from the replacement gate slits 608. Such trim-oxidation cycles may be effectuated via the replacement gate slits 608 to access the sacrificial material within the tiers of the preliminary stack structure 602.

Further, the microelectronic device structure 600 may be subject to replacement gate processing, similar to the replacement gate processing described above with reference to FIG. 2Q, to convert the preliminary stack structure 602 to a stack structure similar to the stack structure 282 (FIG. 2Q). As a result of the replacement gate processing, the microelectronic device structure 600 may comprise a stack structure that includes a vertically alternating (e.g., in the Z-direction) sequence of insulative material and conductive material arranged in tiers. The replacement gate processing may be carried out on the preliminary stack structure 602 through the replacement gate slits 608, similar to the replacement gate processing described above regarding the replacement gate slits 108 and linear holes 110.

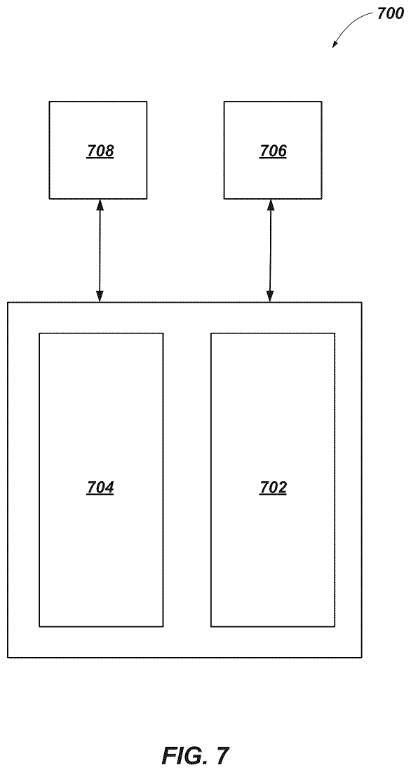

Microelectronic devices structures (e.g., the microelectronic device structure 100, 300, 400, 500, 600 previously described with reference to one or more of FIGS. 1 through 6) in accordance with embodiments of the disclosure may be used in embodiments of electronic systems of the disclosure. For example, FIG. 7 is a block diagram of an illustrative electronic system 700 according to embodiments of this disclosure. The electronic system 700 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® tablet, a SURFACE® tablet, an electronic book, a navigation device.

The electronic system 700 includes at least one memory device 702. The memory device 702 may comprise, for example, a microelectronic device structure previously described herein (e.g., the microelectronic device structure 100, 300, 400, 500, 600 previously described with reference to one or more of FIGS. 1 through 6). The electronic system 700 may further include at least one electronic signal processor device 704 (often referred to as a “microprocessor”). The electronic signal processor device 704 may, optionally, include a microelectronic device structure previously described herein (e.g., the microelectronic device structure 100, 300, 400, 500, 600 previously described with reference to one or more of FIGS. 1 through 6). While the memory device 702 and the electronic signal processor device 704 are depicted as two (2) separate devices in FIG. 7, in additional embodiments, a single (e.g., only one) memory/processor device having the functionalities of the memory device 702 and the electronic signal processor device 704 may be included in the electronic system 700. In such embodiments, the memory/processor device may include a microelectronic device structure previously described herein (e.g., the microelectronic device structure 100, 300, 400, 500, 600 previously described with reference to one or more of FIGS. 1 through 6). The electronic system 700 may further include one or more input devices 706 for inputting information into the electronic system 700 by a user, such as, for example, a mouse or other pointing device, a keyboard, a touchpad, a button, or a control panel. The electronic system 700 may further include one or more output devices 708 for outputting information (e.g., visual or audio output) to a user such as, for example, a monitor, a display, a printer, an audio output jack, a speaker, etc. In some embodiments, the input device 706 and the output device 708 comprise a single touchscreen device that can be used both to input information to the electronic system 700 and to output visual information to a user. The input device 706 and the output device 708 may communicate electrically with one or more of the memory device 702 and the electronic signal processor device 704.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A method of forming a microelectronic device, comprising:
forming a preliminary stack structure over a base structure, the preliminary stack structure comprising tiers, each tier comprising a sacrificial material and an insulative material vertically neighboring the sacrificial material;
forming a cell slit vertically extending through the preliminary stack structure, the cell slit partially defined by sidewalls of the preliminary stack structure;
forming an oxide separator structure horizontally adjacent to the cell slit and vertically extending through the preliminary stack structure;
forming a sacrificial backfill over exposed surfaces of each of the oxide separator structure, the sidewalls of the preliminary stack structure, and the insulative material of the tiers;
removing the oxide separator structure to form a separator recess;
forming a preliminary separator structure in the separator recess;
forming memory cell material within the cell slit over the preliminary separator structure and the sidewalls of the preliminary stack structure;
forming a separator structure from the preliminary separator structure to form vertical memory string structures vertically extending through the preliminary stack structure and horizontally separated from one another by the separator structure; and
replacing the sacrificial backfill with conductive material after forming the vertical memory string structures.

2. The method of claim 1, wherein forming an oxide separator structure comprises:
forming a mask material over the sidewalls of the preliminary stack structure;
removing portions of the sacrificial material adjacent to the cell slit;
removing portions of the mask material along portions of the sidewalls to form a mask material edge; and
forming the oxide separator structure at the mask material edge.

3. The method of claim 2, further comprising forming additional oxide separator structures horizontally adjacent to the cell slit and vertically extending through the preliminary stack structure, the additional oxide separator structures formed through trim-oxidation cycles individually comprising:
removing portions of the sacrificial material from around a periphery of the cell slit to expose additional portions of the mask material over sidewalls of the preliminary stack structure;
removing the additional portions of the mask material along the sidewalls to form an additional mask material edge; and
oxidizing the additional mask material edge.

4. The method of claim 2, further comprising:
forming a sacrificial fill within the cell slit prior to forming the mask material over the sidewalls of the preliminary stack structure; and
removing the sacrificial fill from within the cell slit prior to removing the oxide separator structure to form the separator recess.

5. The method of claim 4, further comprising:
prior to forming the sacrificial fill within the cell slit, forming a cell slit oxide barrier on exposed surfaces of the mask material within the cell slit; and
after removing the sacrificial fill from within the cell slit, removing the cell slit oxide barrier.

6. The method of claim 5, wherein forming the oxide separator structure at the mask material edge further comprises forming the oxide separator structure at the cell slit oxide barrier.

7. The method of claim 1, wherein forming the memory cell material comprises:
forming a barrier oxide material over the sidewalls of the preliminary stack structure and over the preliminary separator structure;
forming a storage nitride material over the barrier oxide material;
forming a band engineered tunnel oxide material over the storage nitride material; and
forming a semiconductor material over the band engineered tunnel oxide material.

8. The method of claim 1, further comprising forming a top masking material over the preliminary stack structure prior to forming the oxide separator structure.

9. The method of claim 1, further comprising:
forming a linear hole vertically extending through the preliminary stack structure, the linear hole having a substantially circular horizontal cross-sectional shape; and
forming a replacement gate slit vertically extending through the preliminary stack structure, the replacement gate slit having a substantially rectangular horizontal cross-sectional shape.

10. The method of claim 9, wherein forming the linear hole comprises forming the linear hole to be horizontally offset from the cell slit in each of a first direction and a second direction orthogonal to the first direction, a portion of the preliminary stack structure horizontally offset from the linear hole in the first direction and horizontally overlapping the linear hole in the second direction.

11. The method of claim 1, wherein forming a separator structure from the preliminary separator structure comprises:
removing a portion of the memory cell material adjacent to the preliminary separator structure to form a separator structure gap;
oxidizing semiconductor material of the preliminary separator structure to form a separator oxide material;
oxidizing additional semiconductor material of the preliminary separator structure horizontally neighboring the separator oxide material to form additional separator oxide material separated from the separator oxide material by the separator structure gap; and
forming a fill material within the separator structure gap.

12. The method of claim 11, wherein oxidizing semiconductor material of the preliminary separator structure and oxidizing additional semiconductor material of the preliminary separator structure are conducted in a single processing act.

13. A microelectronic device, comprising:
a stack structure comprising tiers each including conductive material vertically neighboring insulative material, the stack structure divided into blocks horizontally extending in parallel in a first direction and separated from one another in a second direction orthogonal to the first direction, at least one of the blocks comprising:
filled cell slits vertically extending completely through the tiers of the stack structure and individually defined by two sidewalls of the stack structure horizontally extending in the second direction;
separator structures vertically extending through the tiers and positioned at and around outer horizontal boundaries of the filled cell slits, the separator structures horizontally spaced from one another and individually comprising dielectric oxide vertically extending completely through the tiers of the stack structure; and
vertical memory string structures positioned at and around the outer horizontal boundaries of the filled cell slits and horizontally alternating with the separator structures, the vertical memory string structures comprising semiconductor material vertically extending completely through the tiers of the stack structure; and
filled slot structures horizontally alternating with the blocks of the stack structure in the second direction and vertically extending completely through stack structure.

14. The microelectronic device of claim 13, further comprising filled linear holes within a horizontal area of the at least one of the blocks and vertically extending completely through the tiers of the stack structure, the filled linear holes at least partially horizontally offset from the filled cell slits in each of the first direction and the second direction.

15. The microelectronic device of claim 13, wherein the filled slot structures horizontally extend in parallel with one another and the blocks in the first direction.

16. The microelectronic device of claim 13, wherein:
some of the vertical memory string structures are substantially horizontally aligned with one another in the first direction; and
some others of the vertical memory string structures are substantially horizontally aligned with one another in the second direction.

17. The microelectronic device of claim 16, further comprising memory cells located at intersections of the vertical memory string structures and the conductive material of the tiers of the stack structure.

18. The microelectronic device of claim 13, wherein the vertical memory string structures individually comprise:
a barrier oxide material horizontally adjacent to the conductive material of the tiers of the stack structure;
a storage nitride material horizontally adjacent to the barrier oxide material;
a band engineered tunnel oxide material horizontally adjacent to the storage nitride material; and
the semiconductor material horizontally adjacent to the band engineered tunnel oxide material.

19. A memory device, comprising:
a stack structure comprising blocks horizontally extending in parallel in a first direction and individually including tiers each comprising conductive material and insulative material vertically neighboring the conductive material, the blocks individually comprising:
a filled cell slit vertically extending through the tiers and comprising:
memory string structures vertically extending through all of the tiers and individually comprising:
dielectric oxide material inwardly horizontally adjacent to the conductive material of the tiers;
dielectric nitride material inwardly horizontally adjacent to the dielectric oxide material;
additional dielectric oxide material inwardly horizontally adjacent to the dielectric nitride material; and
semiconductor material inwardly horizontally adjacent to the additional dielectric oxide material;
dielectric oxide separator structures vertically extending through all of the tiers and individually horizontally extending from and between pairs of the memory string structures horizontally neighboring one another in a second direction orthogonal to the first direction; and
dielectric-filled trenches vertically extending completely through the stack structure and horizontal alternating with the blocks in the second direction.

20. The memory device of claim 19, the blocks of the stack structure individually further comprising dielectric-filled holes vertically extending completely through all of the tiers, the dielectric-filled holes each at least partially horizontally offset from the filled cell slit in each of the first direction and the second direction.
